(19) United States
(12) Patent Application Publication
(10) Pub. No.: US 2022/0325208 A1
(43) Pub. Date: Oct. 13, 2022

(54) CLEANING SOLUTION AND CLEANING METHOD

(71) Applicant: FUJIFILM Corporation, Tokyo (JP)

(72) Inventor: Tetsuya KAMIMURA, Shizuoka (JP)

(73) Assignee: FUJIFILM Corporation, Tokyo (JP)

(21) Appl. No.: 17/848,971

(22) Filed: Jun. 24, 2022

Related U.S. Application Data
(63) Continuation of application No. PCT/JP2020/043359, filed on Nov. 20, 2020.

(30) Foreign Application Priority Data
Dec. 26, 2019 (JP) 2019-236122
Jun. 3, 2020 (JP) 2020-097212

(51) Int. Cl. C11D 11/00; C11D 1/37; C11D 3/30; C11D 3/36; C11D 3/20; C11D 3/34; C11D 3/33; C11D 3/22; C11D 3/28; H01L 21/02

(52) U.S. Cl. CPC C11D 11/0047; C11D 1/37; C11D 3/30; C11D 3/361; C11D 3/2086; C11D 3/349; C11D 3/2082; C11D 3/33; C11D 3/2096; C11D 3/3427; C11D 3/222; C11D 3/28; H01L 21/02074; C11D 1/345

(57) ABSTRACT

The present invention provides: a cleaning liquid for semiconductor substrates having undergone CMP, the cleaning liquid being excellent in temporal stability and cleaning performance; and a method of cleaning such semiconductor substrates. A cleaning liquid of the invention contains: a first amine compound which is represented by Formula (1) and whose conjugated acid has a first acidity constant of not less than 8.5; and a second amine compound (provided that the first amine compound is excluded). The mass ratio of the first amine compound content to the second amine compound content is 1 to 100, and the cleaning liquid has pH of 6.0-12.0 at 25° C.

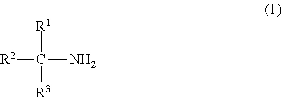

### CROSS-REFERENCE TO RELATED APPLICATIONS

This application is a Continuation of PCT International Application No. PCT/JP2020/043359 filed on Nov. 20, 2020, which claims priority under 35 U.S.C. § 119(a) to Japanese Patent Application No. 2019-236122 filed on Dec. 26, 2019 and Japanese Patent Application No. 2020-097212 filed on Jun. 3, 2020. Each of the above applications is hereby expressly incorporated by reference, in its entirety, into the present application.

### BACKGROUND OF THE INVENTION

The present invention relates to a cleaning liquid for semiconductor substrates and a method of cleaning semiconductor substrates.

Semiconductor devices such as charge-coupled devices (CCDs) and memories are manufactured by forming fine electronic circuit patterns on substrates using the photolithography technology. Specifically, a semiconductor device is manufactured by forming a resist film on a laminate including a metal film which is a wiring material, an etching stop layer and an interlayer dielectric layer on a substrate and carrying out a photolithography step and a dry etching step (e.g., plasma etching).

In some cases, a dry etching residue (for instance, metal components such as titanium-based metal derived from a metallic hard mask, or organic components derived from a photoresist film) remains on a substrate having undergone the dry etching step.

In manufacture of semiconductor devices, a chemical mechanical polishing (CMP) process is sometimes carried out to planarize a surface of a substrate having a metal wiring film, a barrier metal, an insulating film and the like by use of an abrasive slurry containing fine abrasive particles (e.g., silica, alumina). In the CMP process, metal components derived from the fine abrasive particles used in the CMP process and from the metal wiring film, the barrier metal and/or the like having been polished tend to remain on the surface of the semiconductor substrate after polishing.

Since those residues may cause a short-circuit between wires and affect electrical properties of a semiconductor, a cleaning step for removing the residues from the surface of the semiconductor substrate is usually carried out.

For instance, JP 2008-528762 A describes a composition for processing of microelectronic device structures, the composition comprising (i) alkanolamine, (ii) quaternary ammonium hydroxide, and (iii) a specific complexing agent.

### SUMMARY OF THE INVENTION

The present inventor made a study on a cleaning liquid that is used for semiconductor substrates having undergone CMP and contains an aliphatic amine such as an alkanolamine by reference to, for example, JP 2008-528762 A and as a result found that in an aliphatic amine in which a carbon atom situated at the a position of an amino group has a hydrogen atom, the amino group oxidizes with time and forms an N-oxide group (>N═O), and this N-oxide group may corrode a metal film of a semiconductor substrate or may be bonded to metal contained in a residue to form a residue that is hard to remove. On the other hand, the present inventor found that an aliphatic amine in which a carbon atom situated at the a position of an amino group has no hydrogen atom also may affect cleaning performance of the cleaning liquid.

Thus, the present inventor found that there is a room for further improvement in temporal stability and cleaning performance of a cleaning liquid containing an aliphatic amine such as an alkanolamine.

An object of the present invention is to provide a cleaning liquid for semiconductor substrates having undergone CMP, the cleaning liquid being excellent in temporal stability and cleaning performance. Another object of the present invention is to provide a method of cleaning semiconductor substrates having undergone CMP.

The present inventors found that the above objects can be attained with the following configuration.

[1] A cleaning liquid for semiconductor substrates having undergone a chemical mechanical polishing process, the cleaning liquid comprising: a first amine compound which is a compound represented by Formula (1) to be described later and whose conjugated acid has a first acidity constant of not less than 8.5; and a second amine compound which is at least one selected from the group consisting of a primary aliphatic amine having a primary amino group in a molecule (provided that the first amine compound is excluded), a secondary aliphatic amine having a secondary amino group in a molecule, a tertiary aliphatic amine having a tertiary amino group in a molecule, and a quaternary ammonium compound that is a compound having a quaternary ammonium cation or its salt, wherein a mass ratio of a content of the first amine compound to a content of the second amine compound is 1 to 100, and the cleaning liquid has a pH of 6.0 to 12.0 at 25° C.
[2] The cleaning liquid according to [1], wherein a first acidity constant of a conjugated acid of the second amine compound is not less than 8.5.
[3] The cleaning liquid according to [1] or [2], wherein the content of the first amine compound is 0.5 to 25 mass % based on a total mass of the cleaning liquid.
[4] The cleaning liquid according to any one of [1] to [3], wherein the first amine compound includes a primary amino alcohol.
[5] The cleaning liquid according to any one of [1] to [4], wherein the first amine compound includes 2-amino-2-methyl-1-propanol.
[6] The cleaning liquid according to any one of [1] to [5], wherein the first amine compound comprises two or more first amine compounds.
[7] The cleaning liquid according to any one of [1] to [6], wherein the second amine compound includes an amino alcohol.
[8] The cleaning liquid according to any one of [1] to [7], wherein the second amine compound includes 2-(methylamino)-2-methyl-1-propanol.
[9] The cleaning liquid according to any one of [1] to [8], wherein the second amine compound comprises two or more second amine compounds.
[10] The cleaning liquid according to any one of [1] to [9], further comprising at least one selected from the group consisting of an organic acid, a reducing agent, an anionic surfactant, a nitrogen-containing heteroaromatic compound, and a specific chelating agent in which a coordination group is a nitrogen-containing group.
[11] The cleaning liquid according to any one of [1] to [10], further comprising two or more organic acids.
[12] The cleaning liquid according to any one of [1] to [11], further comprising two or more reducing agents.
[13] The cleaning liquid according to any one of [1] to [12], further comprising two or more anionic surfactants.
[14] The cleaning liquid according to any one of [1] to [13], further comprising a nitrogen-containing heteroaromatic compound.
[15] The cleaning liquid according to any one of [1] to [14], further comprising a specific chelating agent in which a coordination group is a nitrogen-containing group.
[16] The cleaning liquid according to any one of [1] to [15], further comprising both a nitrogen-containing heteroaromatic compound and a specific chelating agent in which a coordination group is a nitrogen-containing group.
[17] The cleaning liquid according to any one of [1] to [16], wherein the semiconductor substrate has a metal film containing at least one selected from the group consisting of copper, tungsten, and cobalt.
[18] A method of cleaning semiconductor substrates, the method comprising a step of cleaning a semiconductor substrate having undergone a chemical mechanical polishing process by applying the cleaning liquid according to any one of [1] to [17] to the semiconductor substrate.

The present invention makes it possible to provide a cleaning liquid for semiconductor substrates having undergone CMP, the cleaning liquid being excellent in temporal stability and cleaning performance. The present invention also makes it possible to provide a method of cleaning semiconductor substrates having undergone CMP.

### DETAILED DESCRIPTION OF THE INVENTION

One exemplary embodiment of the invention is described below.

In this specification, a numerical range expressed in the form of “A to B” should read as a range including both the values A and B as the range's lower and upper limits, respectively.

In this specification, when a certain component comprising two or more types is present, the “content” of the certain component means the total content of the two or more types.

In this specification, “ppm” means “parts per million (10⁻⁶),” and “ppb” means “parts per billion (10⁻⁹).”

In compounds described in this description, isomers (compounds with the same number of atoms but different structures), optical isomers, and isotopes may be included unless particularly limited. As isomers and isotopes, only one type or plural types may be included.

In this specification, “psi” refers to “pound-force per square inch,” and 1 psi=6894.76 Pa.

A cleaning liquid of the invention (hereinafter also simply called “cleaning liquid”) is a cleaning liquid for semiconductor substrates having undergone a chemical mechanical polishing (CMP) process, the cleaning liquid comprising: a first amine compound (hereinafter also called “first amine”) which is represented by Formula (1) below and whose conjugated acid has a first acidity constant of not less than 8.5; and a second amine compound (hereinafter also called “second amine”) which is at least one selected from the group consisting of specific primary aliphatic amine, secondary aliphatic amine, tertiary aliphatic amine, and quaternary ammonium compound. The mass ratio of the first amine content to the second amine content in the cleaning liquid is 1 to 100, and the pH of the cleaning liquid at 25° C. is 6.0 to 12.0.

The present inventor found that when a cleaning liquid contains the first amine and the second amine and also when the ratio between the first and second amine contents and the pH of the cleaning liquid are specified, the temporal stability and cleaning performance of the cleaning liquid used in a cleaning step of semiconductor substrates having undergone CMP (hereinafter also simply called “effects of the invention”) are improved.

Although the precise mechanism is unclear why the effects of the invention are obtained by use of the cleaning liquid as above, the present inventor assumes that the temporal stability of the cleaning liquid improves because in the first amine represented by Formula (1) below, a carbon atom situated at the a position of an amino group has no hydrogen atom so that no N-oxide group is formed and that the cleaning performance of the cleaning liquid improves because containing a specific amount of the second amine compound causes increased solubility of the first amine with respect to the cleaning liquid.

### [Cleaning Liquid]

Each component contained in the cleaning liquid is described below.

### [First Amine Compound (First Amine)]

The cleaning liquid of the invention contains the first amine compound (first amine) which is represented by Formula (1) below and whose conjugated acid has a first acidity constant of not less than 8.5.

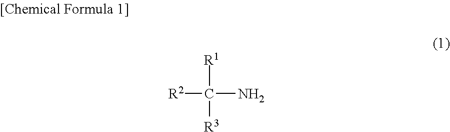

In Formula (1), R¹, R² and R³ each represent an organic group. Some of R¹, R² and R³ may be bonded together to form a non-aromatic ring that may have a substituent.

Examples of the organic group represented by R¹, R² and R³ include an alkyl group, an alkenyl group, an alkynyl group, a cycloalkyl group, and an aryl group. These groups may further have a substituent. Examples of the substituent include a hydroxy group and an amino group. The alkyl group, the alkenyl group and the alkynyl group may be linear or branched.

The number of carbon atoms of the organic group represented by R¹, R² and R³ is not particularly limited and is preferably 1 to 10, more preferably 1 to 5, and even more preferably 1 to 3.

The non-aromatic ring that may have a substituent as formed by bonding of some of R¹, R² and R³ is not particularly limited, and examples thereof include a cycloalkane ring having 5 to 10 carbon atoms, with preferred being a cyclopentane ring, cyclohexane ring, or a cycloheptane ring.

Examples of the substituent that the non-aromatic ring may have include an alkyl group having 1 to 4 carbon atoms.

For the organic group represented by R¹, R² and R³, an alkyl group that may have a hydroxy group is preferred, an alkyl group having 1 to 5 carbon atoms that may have a hydroxy group is more preferred, an alkyl group having 1 to 3 carbon atoms that may have a hydroxy group is even more preferred, and a methyl group or ethyl group that may have a hydroxy group is particularly preferred.

In particular, more preferred is the combination of zero to two of R¹, R² and R³ being an alkyl group having a hydroxy group and the remaining one to three thereof being an alkyl group having no hydroxy group.

The first amine preferably includes a primary amino alcohol because this leads to more excellent temporal stability of the cleaning liquid. In other words, at least one of the organic groups represented by R¹, R² and R³ in Formula (1) above preferably has a hydroxy group.

For the primary amino alcohol, preferably, one or two of the organic groups represented by R¹, R² and R³ have a hydroxy group, and more preferably, only one of the organic groups represented by R¹, R² and R³ has a hydroxy group.

The first acidity constant (hereinafter referred to also as “pKa1”) of the conjugated acid of the first amine is not less than 8.5. The first amine with pKa1 of not less than 8.5 leads to more stable pH of the cleaning liquid as well as improved cleaning performance and corrosion prevention performance of the cleaning liquid.

The first amine has pKa1 of preferably not less than 8.8 and more preferably not less than 9.0 because this leads to more excellent cleaning performance and corrosion prevention performance. The upper limit thereof is not particularly limited and is preferably not more than 12.0.

Examples of the first amine included in the primary amino alcohol include 2-amino-2-methyl-1-propanol (AMP) (pKa1: 9.72), 2-amino-2-methyl-1,3-dipropanol (AMPD) (pKa1: 8.80), and 2-amino-2-ethyl-1,3-dipropanol (AEPD) (pKa1: 8.80).

Examples of the first amine not included in the primary amino alcohol include tert-butylamine (tBA) (pKa1: 10.68) and tert-amylamine (tAA) (pKa1: 10.50).

For the first amine, AMP, AMPD, or AEPD is preferred, and AMP is more preferred.

The first amines may be used singly or in combination of two or more. It is preferable for the cleaning liquid to contain two or more first amines because this leads to more excellent cleaning performance (particularly with respect to a W-containing metal film).

The first amine content of the cleaning liquid is not particularly limited and is preferably not less than 0.5 mass %, more preferably more than 1 mass %, even more preferably not less than 2 mass % and particularly preferably more than 3 mass % based on the total mass of the cleaning liquid because this leads to more excellent cleaning performance (particularly with respect to a Cu- or Co-containing metal film). The upper limit thereof is not particularly limited and is preferably not more than 25 mass %, more preferably not more than 15 mass %, even more preferably not more than 10 mass % and particularly preferably not more than 7 mass % based on the total mass of the cleaning liquid because this leads to more excellent corrosion prevention performance.

Further, the first amine content is preferably not less than 10 mass %, more preferably not less than 20 mass % and even more preferably not less than 30 mass % based on the total mass of components, excluding a solvent, in the cleaning liquid. The upper limit thereof is preferably not more than 90 mass %, more preferably not more than 80 mass % and even more preferably not more than 70 mass % based on the total mass of components, excluding a solvent, in the cleaning liquid.

In this specification, the expression “the total mass of components, excluding a solvent, in the cleaning liquid” refers to the sum of the contents of all components contained in the cleaning liquid, excluding a solvent. The simple term “solvent” includes both water and an organic solvent.

### [Second Amine Compound (Second Amine)]

The cleaning liquid may contain the second amine compound (second amine) that is at least one selected from the group consisting of a primary aliphatic amine having a primary amino group (—NH₂) in the molecule (provided that the first amine is excluded), a secondary aliphatic amine having a secondary amino group (>NH) in the molecule, a tertiary aliphatic amine having a tertiary amino group (>N—) in the molecule, and a quaternary ammonium compound that is a compound having a quaternary ammonium cation or its salt.

The second amine is described below in separate sections of the primary, secondary and tertiary aliphatic amines (hereinafter also sometimes collectively called “primary to tertiary amines”) and the quaternary ammonium compound.

### <Primary to Tertiary Amines>

The primary to tertiary amines are not particularly limited as long as they are each a compound that has a group selected from the primary amino group, the secondary amino group, and the tertiary amino group (hereinafter also sometimes collectively called “primary to tertiary amino groups”) in the molecule or its salt and is not included in the first amine above.

Examples of salts of the primary to tertiary amines include a salt with an inorganic acid in which at least one non-metal selected from the group consisting of Cl, S, N and P is bonded to hydrogen, and preferred is a hydrochloride, a sulfate, or a nitrate.

Examples of the primary to tertiary amines include an amino alcohol and an alicyclic amine compound, as well as an aliphatic monoamine compound and an aliphatic polyamine compound other than the amino alcohol and the alicyclic amine.

### (Amino Alcohol)

The amino alcohol is, of the primary to tertiary amines, a compound further having at least one hydroxylalkyl group in the molecule. The amino alcohol may have any of primary to tertiary amino groups and preferably has a primary amino group.

Examples of the amino alcohol included in the primary to tertiary amines include monoethanolamine (MEA), diethanolamine (DEA), triethanolamine (TEA), diethylene glycol amine (DEGA), tris(hydroxymethyl)aminomethane (Tris), 2-(methylamino)-2-methyl-1-propanol (N-MAMP), 2-(dimethylamino)-2-methyl-1-propanol (DMAMP), 2-(aminoethoxy)ethanol (AEE), and 2-(2-aminoethylamino)ethanol (AAE).

Of these, N-MAMP, DMAMP, MEA, DEA, AEE, or AAE is preferred, and N-MAMP, DMAMP, MEA, or AEE is more preferred. In terms of providing excellent cleaning performance (particularly with respect to a W-containing metal film), MEA, DEA, AEE, or AAE is more preferred.

### (Alicyclic Amine Compound)

The alicyclic amine compound is not particularly limited as long as it is a compound having a non-aromatic heterocyclic ring in which at least one of atoms constituting the ring is a nitrogen atom.

Examples of the alicyclic amine compound include a piperazine compound and a cyclic amidine compound.

The piperazine compound is a compound having a six-membered heterocyclic ring (piperazine ring) in which opposed —CH— groups in a cyclohexane ring are substituted with nitrogen atoms.

The piperazine compound may have a substituent on the piperazine ring. Examples of the substituent include a hydroxy group, an alkyl group having 1 to 4 carbon atoms that may have a hydroxy group, and an aryl group having 6 to 10 carbon atoms.

Examples of the piperazine compound include piperazine, 1-methylpiperazine, 1-ethylpiperazine, 1-propylpiperazine, 1-butylpiperazine, 2-methylpiperazine, 1,4-dimethylpiperazine, 2,5-dimethylpiperazine, 2,6-dimethylpiperazine, 1-phenylpiperazine, 2-hydroxypiperazine, 2-hydroxymethylpiperazine, 1-(2-hydroxyethyl)piperazine (HEP), N-(2-aminoethyl)piperazine (AEP), 1,4-bis(2-hydroxyethyl)piperazine (BHEP), 1,4-bis(2-aminoethyl)piperazine (BAEP), and 1,4-bis(3-aminopropyl)piperazine (BAPP), with preferred being piperazine, 1-methylpiperazine, 2-methylpiperazine, HEP, AEP, BHEP, BAEP, or BAPP.

The cyclic amidine compound is a compound having a heterocyclic ring including an amidine structure (>N—C═N—) in the ring.

The number of atoms constituting the heterocyclic ring of the cyclic amidine compound is not particularly limited and is preferably 5 or 6 and more preferably 6.

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimido[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimido[1.2-a]azepine, and creatinine.

Examples of the alicyclic amine compound include, in addition to the foregoing examples, a compound having a five-membered heterocyclic ring with no aromatic properties such as 1,3-dimethyl-2-imidazolidinone or imidazolidinethione, and a compound having a seven-membered ring containing a nitrogen atom(s).

### (Aliphatic Monoamine Compound)

The aliphatic monoamine compound other than the amino alcohol and the alicyclic amine is not particularly limited as long as it is a compound not included in the first amine, and examples thereof include methylamine, ethylamine, propylamine, dimethylamine, diethylamine, n-butylamine, 3-methoxypropylamine, tert-butylamine, n-hexylamine, cyclohexylamine, n-octylamine, 2-ethylhexylamine, and 4-(2-aminoethyl)morpholine (AEM).

### (Aliphatic Polyamine Compound)

Examples of the aliphatic polyamine compound other than the amino alcohol and the alicyclic amine include alkylene diamines such as ethylenediamine (EDA), 1,3-propanediamine (PDA), 1,2-propanediamine, 1,3-butanediamine, and 1,4-butanediamine, and polyalkyl polyamines such as diethylenetriamine (DETA), triethylenetetramine (TETA), bis(aminopropyl)ethylenediamine (BAPEDA), and tetraethylenepentamine.

For the primary to tertiary amines, of the compounds described in paragraphs [0034] to [0056] of the description of WO 2013/162020, those not included in the first amine can be applied, and the contents thereof are incorporated in the present specification.

It is preferable for the primary to tertiary amines to further have one or more hydrophilic groups in addition to relevant one of the primary to tertiary amino groups. Examples of the hydrophilic group include the primary to tertiary amino groups and a hydroxy group. Examples of the primary to tertiary amines further having one or more hydrophilic groups in addition to relevant one of the primary to tertiary amino groups include a compound having two or more hydrophilic groups of the amino alcohol, the aliphatic polyamine compound and the alicyclic amine compound, with the amino alcohol being preferred.

The upper limit of the total number of hydrophilic groups that the primary to tertiary amines have is not particularly limited and is preferably not more than 4 and more preferably not more than 3.

The number of the primary to tertiary amino groups that the primary to tertiary amines have is not particularly limited and is preferably 1 to 4 and more preferably 1 to 3.

The upper limit of the molecular weight of the primary to tertiary amines is not particularly limited and is preferably not more than 200 and more preferably not more than 150. The lower limit thereof is not particularly limited and is preferably not less than 60.

### <Quaternary Ammonium Compound>

The quaternary ammonium compound is not particularly limited as long as it is a quaternary ammonium cation-containing compound in which a nitrogen atom is attached to four hydrocarbon groups (preferably, alkyl groups) through substitution, or a salt thereof. Examples of the quaternary ammonium compound include quaternary ammonium hydroxide, quaternary ammonium fluoride, quaternary ammonium bromide, quaternary ammonium iodide, quaternary ammonium acetate, and quaternary ammonium carbonate.

For the quaternary ammonium compound, preferred is quaternary ammonium hydroxide represented by Formula (2):

(R⁴)₄N⁺OH⁻ (2)

where R⁴ represents an alkyl group that may have a hydroxy group or a phenyl group as a substituent. Four R⁴s may be the same or different.

For the alkyl group represented by R⁴, an alkyl group having 1 to 4 carbon atoms is preferred, and a methyl group or an ethyl group is more preferred.

For the alkyl group that may have a hydroxy group or a phenyl group as represented by R⁴, preferred is a methyl group, an ethyl group, a propyl group, a butyl group, a 2-hydroxyethyl group, or a benzyl group, more preferred is a methyl group, an ethyl group, a propyl group, a butyl group, or a 2-hydroxyethyl group, and even more preferred is a methyl group, an ethyl group, or a 2-hydroxyethyl group.

Examples of the quaternary ammonium compound include tetramethylammonium hydroxide (TMAH), trimethylethylammonium hydroxide (TMEAH), diethyldimethylammonium hydroxide (DEDMAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyl trimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide.

As the quaternary ammonium compound other than the foregoing specific examples, the compounds described in paragraph [0021] of JP 2018-107353 A can be applied, and the contents thereof are incorporated in the present description.

For the quaternary ammonium compound used for the cleaning liquid, TMAH, TMEAH, DEDMAH, MTEAH, TEAR, TPAH, TBAH, choline, or bis(2-hydroxyethyl)dimethylammonium hydroxide is preferred, DEDMAH, MTEAH, TEAR, TPAH, or TBAH is more preferred, and MTEAH, TEAH, or TBAH is more preferred.

The first acidity constant (pKa1) of the conjugated acid of the second amine is preferably not less than 8.5, more preferably not less than 8.6 and even more preferably not less than 8.7 because this leads to more excellent temporal stability of the cleaning liquid. The upper limit thereof is not particularly limited and is preferably not more than 12.0.

For the second amine, preferred is any of the primary to tertiary amines corresponding to the amino alcohol or the quaternary ammonium compound, more preferred is N-MAMP (pKa1: 9.72), MEA (pKa1: 9.50), DEA (pKa1: 8.70), AEE (pKa1: 10.60), AAE (pKa1: 10.80), DEDMAH (pKa1: >14.0), MTEAH (pKa1: >14.0), TEAH (pKa1: >14.0), TPAH (pKa1: >14.0), or TBAH (pKa1: >14.0), even more preferred is N-MAMP, MEA, AEE, MTEAH, TEAH, or TBAH, and particularly preferred is N-MAMP, MEA, or AEE.

In terms of providing excellent cleaning performance (particularly with respect to a W-containing metal film), MEA, DEA, AEE, or AAE is more preferred.

The second amines may be used singly or in combination of two or more. It is preferable for the cleaning liquid to contain two or more second amines because this leads to excellent cleaning performance (particularly with respect to a W-containing metal film).

When the cleaning liquid contains two or more second amines, it is preferable to contain one or more primary to tertiary amines corresponding to the amino alcohol and one or more quaternary ammonium compounds, and it is more preferable to contain a combination of compounds separately mentioned as a preferred specific example of the primary to tertiary amines and that of the quaternary ammonium compound.

The second amine content of the cleaning liquid is preferably not less than 0.05 mass %, more preferably not less than 0.5 mass %, even more preferably not less than 1 mass %, and particularly preferably not less than 2 mass % based on the total mass of the cleaning liquid because this leads to more excellent cleaning performance. The upper limit of the second amine content is preferably not more than 20 mass %, more preferably not more than 15 mass % and even more preferably not more than 10 mass % based on the total mass of the cleaning liquid because this leads to excellent corrosion prevention performance with respect to a metal film.

Further, the second amine content is preferably not less than 0.5 mass %, more preferably not less than 1 mass %, even more preferably not less than 2 mass % and particularly preferably not less than 5 mass % based on the total mass of components, excluding a solvent, in the cleaning liquid. The upper limit of the second amine content is preferably not more than 45 mass %, more preferably not more than 40 mass % and even more preferably not more than 30 mass % based on the total mass of components, excluding a solvent, in the cleaning liquid.

In the cleaning liquid of the invention, the mass ratio of the first amine content to the second amine content (first amine content/second amine content) is 1 to 100. When the mass ratio of the first amine content to the second amine content falls within the foregoing range, the cleaning liquid having the effects of the invention can be obtained.

The mass ratio of the first amine content to the second amine content is preferably 2 to 99 and more preferably 5 to 98 because this leads to more excellent effects of the invention.

### [Water]

The cleaning liquid preferably contains water as a solvent.

The type of water used in the cleaning liquid is not particularly limited as long as it has no bad influence on a semiconductor substrate, and distilled water, deionized water and pure water (ultrapure water) are usable. Pure water is preferred because it hardly contains impurities and its influence on a semiconductor substrate is smaller in a semiconductor substrate manufacturing process.

The water content of the cleaning liquid may be the balance other than the first amine, the second amine, and optional components to be described later. The water content is, for instance, preferably not less than 1 mass %, more preferably not less than 30 mass %, even more preferably not less than 60 mass %, and particularly preferably not less than 85 mass % based on the total mass of the cleaning liquid. The upper limit thereof is not particularly limited and is preferably not more than 99 mass % and more preferably not more than 95 mass % based on the total mass of the cleaning liquid.

### [Optional Component]

The cleaning liquid may contain other optional components in addition to the foregoing components. Exemplary optional components include an organic acid, a reducing agent, a surfactant, a nitrogen-containing heteroaromatic compound, a chelating agent in which a coordination group is a nitrogen-containing group (hereinafter also called “specific chelating agent”), and various additives.

The cleaning liquid preferably contains at least one selected from the group consisting of an organic acid, a reducing agent, a surfactant (more preferably, an anionic surfactant), a nitrogen-containing heteroaromatic compound, and the specific chelating agent.

The optional components may be used singly or in combination of two or more.

Optional components are described below.

### <Organic Acid>

The organic acid is an organic compound having an acidic functional group and showing acidic properties (pH: less than 7.0) in an aqueous solution. Examples of the acidic functional group include a carboxyl group, a phosphonic acid group, a sulfo group, a phenolic hydroxy group, and a mercapto group.

Note that in this specification, compounds serving as the anionic surfactant to be described later are not included in the organic acid.

The organic acid is not particularly limited, and examples thereof include a carboxylic acid having a carboxyl group in the molecule (organic carboxylic acid), a phosphonic acid having a phosphonic acid group in the molecule (organic phosphonic acid), and a sulfonic acid having a sulfo group in the molecule (organic sulfonic acid), with a carboxylic acid or a phosphonic acid being preferred.

The number of the functional groups of the organic acid is not particularly limited, and is preferably 1 to 4 and more preferably 1 to 3.

The organic acid is preferably a compound having the function of chelating with metal contained in a residue because this leads to more excellent cleaning performance, and more preferably a compound having in the molecule two or more functional groups (coordination groups) that form coordinate bonds with a metal ion. Exemplary coordination groups include the foregoing functional groups, with a carboxylic acid group or a phosphonic acid group being preferred.

### (Carboxylic Acid)

The carboxylic acid may be a monocarboxylic acid having one carboxyl group or a polycarboxylic acid having two or more carboxyl groups. Preferred is a polycarboxylic acid having two or more (preferably two to four and more preferably two or three) carboxyl groups because this leads to more excellent cleaning performance.

Examples of the carboxylic acid include an aminopolycarboxylic acid, an amino acid, a hydroxy carboxylic acid, and an aliphatic carboxylic acid.

### —Aminopolycarboxylic Acid—

The aminopolycarboxylic acid is a compound having one or more amino groups and two or more carboxy groups as coordination groups in the molecule.

Examples of the aminopolycarboxylic acid include aspartic acid, glutamic acid, butylene diamine tetraacetic acid, diethylenetriamine pentaacetic acid (DTPA), ethylenediamine tetrapropionic acid, triethylenetetramine hexacetic acid, 1,3-diamino-2-hydroxypropane-N,N,N′,N′-tetraacetic acid, propylenediamine tetraacetic acid, ethylenediamine tetraacetic acid (EDTA), trans-1,2-diaminocyclohexane tetraacetic acid (CyDTA), ethylenediamine diacetic acid, ethylenediamine dipropionic acid, 1,6-hexamethylene-diamine-N,N,N′,N′-tetraacetic acid, N,N-bis(2-hydroxybenzyl)ethylenediamine-N,N-diacetic acid, diaminopropane tetraacetic acid, 1,4,7,10-tetraazacyclododecane-tetraacetic acid, diaminopropanol tetraacetic acid, (hydroxyethyl)ethylenediamine triacetic acid, and iminodiacetic acid (IDA).

Of these, DTPA, EDTA, CyDTA, or IDA is preferred.

### —Amino Acid—

The amino acid is a compound having one carboxyl group and one or more amino groups in the molecule.

Examples of the amino acid include glycine, serine, α-alanine (2-aminopropionic acid), β-alanine (3-aminopropionic acid), lysine, leucine, isoleucine, cysteine, methionine, ethionine, threonine, tryptophan, tyrosine, valine, histidine, histidine derivatives, asparagine, glutamine, arginine, proline, phenylalanine, the compounds described in paragraphs [0021] to [0023] of JP 2016-086094 A, and salts thereof. For the histidine derivatives, the compounds described in JP 2015-165561 A, JP 2015-165562 A and the like can be applied, and the contents thereof are incorporated in the present specification. Examples of the salts include alkali metal salts such as a sodium salt and a potassium salt, ammonium salts, carbonates, and acetates.

In particular, a sulfur-containing amino acid containing a sulfur atom, or β-alanine is preferred. Examples of the sulfur-containing amino acid include cystine, cysteine, ethionine, and methionine, with cystine or cysteine being preferred.

### —Hydroxy Carboxylic Acid—

The hydroxy carboxylic acid is a compound having one or more hydroxy groups and one or more amino groups in the molecule.

The cleaning liquid preferably contains the hydroxy carboxylic acid because this allows the cleaning liquid to have further improved cleaning performance (particularly with respect to a Co- or Cu-containing metal film) while maintaining corrosion prevention performance (particularly with respect to a Co- or Cu-containing metal film).

Examples of the hydroxy carboxylic acid include malic acid, citric acid, glycolic acid, gluconic acid, heptonic acid, tartaric acid, and lactic acid, with preferred being gluconic acid, glycolic acid, malic acid, tartaric acid, or citric acid, and more preferred being gluconic acid or citric acid.

### —Aliphatic Carboxylic Acid—

Examples of the aliphatic carboxylic acid include oxalic acid, malonic acid, succinic acid, glutaric acid, adipic acid, pimelic acid, sebacic acid, and maleic acid, with preferred being adipic acid or succinic acid. In particular, an adipic acid is more preferred because the use thereof results in remarkable improvement in performance (cleaning performance and corrosion prevention performance) of the cleaning liquid as compared to other chelating agents. Although the precise mechanism of such a distinctive effect of an adipic acid is unclear, the effect is assumed to be derived from the fact that an adipic acid has particularly excellent hydrophilicity and hydrophobicity due to the relationship between the number of carbon atoms of an alkylene group and two carboxy groups and therefore forms a stable ring structure in formation of a complex with metal.

Other than the foregoing aminopolycarboxylic acid, amino acid, hydroxy carboxylic acid, and aliphatic carboxylic acid, examples of the carboxylic acid include a monocarboxylic acid.

Examples of the monocarboxylic acid include lower aliphatic monocarboxylic acids (with 1 to 4 carbon atoms) such as formic acid, acetic acid, propionic acid, and butyric acid.

For the carboxylic acid, preferred is the amino acid, the hydroxy carboxylic acid, or the aliphatic carboxylic acid, more preferred is cystine, cysteine, gluconic acid, glycolic acid, malic acid, tartaric acid, citric acid, or adipic acid, and even more preferred is cysteine, gluconic acid, citric acid, or adipic acid.

The carboxylic acids may be used singly or in combination of two or more.

The carboxylic acid content of the cleaning liquid is not particularly limited and is preferably not more than 10 mass % and more preferably not more than 5 mass % based on the total mass of the cleaning liquid. The lower limit thereof is not particularly limited and is preferably not less than 0.1 mass % and more preferably not less than 0.5 mass % based on the total mass of the cleaning liquid.

Further, the carboxylic acid content is preferably not more than 25 mass % and more preferably not more than 15 mass % based on the total mass of components, excluding a solvent, in the cleaning liquid. The lower limit thereof is preferably not less than 1 mass % and more preferably not less than 3 mass % based on the total mass of components, excluding a solvent, in the cleaning liquid.

### (Phosphonic Acid)

The phosphonic acid may be a monophosphonic acid having one phosphonic acid group or a polyphosphonic acid having two or more phosphonic acid groups. A polyphosphonic acid having two or more phosphonic acid groups is preferred because this leads to more excellent cleaning performance.

Examples of the polyphosphonic acid include compounds represented by Formulae (P1), (P2) and (P3) below.

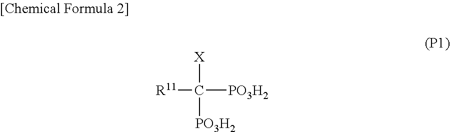

In the formula, X represents a hydrogen atom or a hydroxy group, and R¹¹ represents a hydrogen atom or an alkyl group having 1 to 10 carbon atoms.

The alkyl group having 1 to 10 carbon atoms represented by R₁₁ in Formula (P1) may be any of linear, branched and cyclic groups.

For R¹¹ in Formula (P1), an alkyl group having 1 to 6 carbon atoms is preferred, and a methyl group, an ethyl group, an n-propyl group, or an isopropyl group is more preferred.

It should be noted that n- represents a normal-type in specific examples of an alkyl group described in the present specification.

For X in Formula (P1), a hydroxy group is preferred.

For the polyphosphonic acid represented by Formula (P1), preferred is ethylidenediphosphonic acid, 1-hydroxyethylidene-1,1′-diphosphonic acid (HEDPO), 1-hydroxypropylidene-1,1′-diphosphonic acid, or 1-hydroxybutylidene-1,1′-diphosphonic acid.

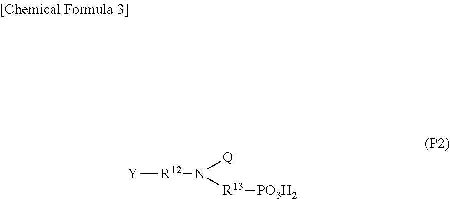

In the formula, Q represents a hydrogen atom or R¹³—PO₃H₂, R¹² and R¹³ each independently represent an alkylene group, and Y represents a hydrogen atom, —R¹³—PO₃H₂, or a group represented by Formula (P4) below.

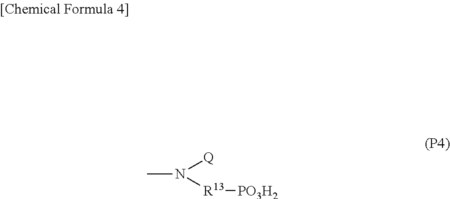

In the formula, Q and R¹³ are the same as those in Formula (P2).

Examples of the alkylene group represented by R¹² in Formula (P2) include a linear or branched alkylene group having 1 to 12 carbon atoms.

For the alkylene group represented by R¹², a linear or branched alkylene group having 1 to 6 carbon atoms is preferred, a linear or branched alkylene group having 1 to 4 carbon atoms is more preferred, and an ethylene group is even more preferred.

For the alkylene group represented by R¹³ in Formulae (P2) and (P4), examples thereof include a linear or branched alkylene group having 1 to 10 carbon atoms, with a linear or branched alkylene group having 1 to 4 carbon atoms being preferred, a methylene group or an ethylene group being more preferred, and a methylene group being even more preferred.

For Q in Formulae (P2) and (P4), —R¹³—PO₃H₂ is more preferred.

For Y in Formula (P2), —R¹³—PO₃H₂ or the group represented by Formula (P4) is preferred, and the group represented by Formula (P4) is more preferred.

For the polyphosphonic acid represented by Formula (P2), preferred is ethylaminobis(methylenephosphonic acid), dodecylaminobis(methylenephosphonic acid), nitrilotris(methylenephosphonic acid) (NTPO), ethylenediamine bis(methylenephosphonic acid) (EDDPO), 1,3-propylenediamine bis(methylenephosphonic acid), ethylenediamine tetra(methylenephosphonic acid) (EDTPO), ethylenediamine tetra(ethylenephosphonic acid), 1,3-propylenediamine tetra(methylenephosphonic acid) (PDTMP), 1,2-diaminopropane tetra(methylenephosphonic acid), or 1,6-hexamethylenediamine tetra(methylenephosphonic acid).

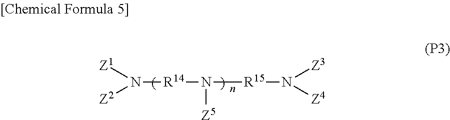

In the formula, R¹⁴ and R¹⁵ each independently represent an alkylene group having 1 to 4 carbon atoms, n represents an integer of 1 to 4, and at least four of Z¹ to Z⁴ and n moieties of Z⁵s represent a phosphonic acid group-containing alkyl group while the remainder represents an alkyl group.

The alkylene group having 1 to 4 carbon atoms represented by R¹⁴ and R¹⁵ in Formula (P3) may be linear or branched. Examples of the alkylene group having 1 to 4 carbon atoms represented by R¹⁴ and R¹⁵ include a methylene group, an ethylene group, a propylene group, a trimethylene group, an ethylmethylene group, a tetramethylene group, a 2-methylpropylene group, a 2-methyltrimethylene group, and an ethylethylene group, with an ethylene group being preferred.

For n in Formula (P3), 1 or 2 is preferred.

Examples of an alkyl group in the alkyl group and the phosphonic acid group-containing alkyl group represented by Z¹ to Z⁵ in Formula (P3) include a linear or branched alkyl group having 1 to 4 carbon atoms, with a methyl group being preferred.

The number of phosphonic acid groups in the phosphonic acid group-containing alkyl group represented by Z¹ to Z⁵ is preferably 1 or 2 and more preferably 1.

Examples of the phosphonic acid group-containing alkyl group represented by Z¹ to Z⁵ include a linear or branched alkyl group having 1 to 4 carbon atoms and one or two phosphonic acid groups, with a (mono)phosphonomethyl group or a (mono)phosphonoethyl group being preferred, and a (mono)phosphonomethyl group being more preferred.

For Z¹ to Z⁵ in Formula (P3), it is preferable that each of Z¹ to Z⁴ and n moieties of Z⁵s be the foregoing phosphonic acid group-containing alkyl group.

For the polyphosphonic acid represented by Formula (P3), preferred is diethylenetriamine penta(methylenephosphonic acid) (DEPPO), diethylenetriamine penta(ethylenephosphonic acid), triethylenetetramine hexa(methylenephosphonic acid), or triethylenetetramine hexa(ethylenephosphonic acid).

For the polyphosphonic acid used in the cleaning liquid, not only the polyphosphonic acids represented by Formulae (P1), (P2) and (P3) above but also the compounds described in paragraphs [0026] to [0036] of the description of WO 2018/020878 and the compounds ((co)polymers) described in paragraphs [0031] to [0046] of the description of WO 2018/030006 can be applied, and the contents thereof are incorporated in the present specification.

The number of phosphonic acid groups in the phosphonic acid is preferably 2 to 5, more preferably 2 to 4, and even more preferably 2 or 3.

The number of carbon atoms in the phosphonic acid is preferably not more than 12, more preferably not more than 10 and even more preferably not more than 8. The lower limit thereof is not particularly limited and is preferably not less than 1.

For the phosphonic acid, those compounds listed as preferable specific examples of the polyphosphonic acids represented by Formulae (P1), (P2) and (P3) above are preferred, and HEDPO is more preferred.

The phosphonic acids may be used singly or in combination of two or more.

The phosphonic acid content of the cleaning liquid is not particularly limited and is preferably not more than 2 mass % and more preferably not more than 1 mass % based on the total mass of the cleaning liquid. The lower limit thereof is not particularly limited and is preferably not less than 0.01 mass % and more preferably not less than 0.05 mass % based on the total mass of the cleaning liquid.

Further, the phosphonic acid content is preferably not more than 5 mass % and more preferably not more than 3 mass % based on the total mass of components, excluding a solvent, in the cleaning liquid. The lower limit thereof is preferably not less than 0.1 mass % and more preferably not less than 0.5 mass % based on the total mass of components, excluding a solvent, in the cleaning liquid.

The organic acid is preferably of low molecular weight. Specifically, the molecular weight of the organic acid is preferably not more than 600, more preferably not more than 450 and even more preferably not more than 300. The lower limit thereof is not particularly limited and is preferably not less than 85.

The number of carbon atoms in the organic acid is preferably not more than 15, more preferably not more than 12 and even more preferably not more than 8. The lower limit thereof is not particularly limited and is preferably not less than 2.

The organic acids may be used singly or in combination of two or more. It is preferable for the cleaning liquid to contain two or more organic acids because this leads to excellent cleaning performance (particularly with respect to a W-containing metal film).

The organic acid content of the cleaning liquid is not particularly limited and is preferably not more than 10 mass % and more preferably not more than 5 mass % based on the total mass of the cleaning liquid. The lower limit thereof is not particularly limited and is preferably not less than 0.01 mass % and more preferably not less than 0.05 mass % based on the total mass of the cleaning liquid.

Further, the organic acid content is preferably not more than 25 mass % and more preferably not more than 15 mass % based on the total mass of components, excluding a solvent, in the cleaning liquid. The lower limit thereof is preferably not less than 0.1 mass % and more preferably not less than 0.5 mass % based on the total mass of components, excluding a solvent, in the cleaning liquid.

### <Reducing Agent>

The reducing agent is a compound having an oxidative effect and having the function of oxidizing OH⁻ ions or dissolved oxygen contained in the cleaning liquid, and is also called an oxygen scavenger. The cleaning liquid preferably contains the reducing agent because this leads to more excellent corrosion prevention performance of the cleaning liquid.

The reducing agent used in the cleaning liquid is not particularly limited, and examples thereof include an ascorbic acid compound, a catechol compound, a hydroxylamine compound, a hydrazide compound, and a reducing sulfur compound.

### —Ascorbic Acid Compound—

The ascorbic acid compound refers to at least one selected from the group consisting of ascorbic acid, an ascorbic acid derivative, and their salts.

Examples of the ascorbic acid derivative include an ascorbic acid phosphoric acid ester and an ascorbic acid sulfuric acid ester.

For the ascorbic acid compound, preferred is ascorbic acid, ascorbic acid phosphoric acid ester, or ascorbic acid sulfuric acid ester, and more preferred is ascorbic acid.

### —Catechol Compound—

The catechol compound refers to at least one selected from the group consisting of pyrocatechol(benzene-1,2-diol) and a catechol derivative.

The catechol derivative refers to a compound of pyrocatechol obtained through substitution with at least one substituent. Examples of the substituent that the catechol derivative has include a hydroxy group, a carboxy group, a carboxylic acid ester group, a sulfo group, a sulfonic acid ester group, an alkyl group (preferably with 1 to 6 carbon atoms and more preferably with 1 to 4 carbon atoms), and an aryl group (preferably a phenyl group). The carboxy group and the sulfo group that the catechol derivative has as substituents may be salts of a cation. The alkyl group and the aryl group that the catechol derivative has as substituents may further have a substituent.

Examples of the catechol compound include pyrocatechol, 4-tert-butylcatechol, pyrogallol, gallic acid, methyl gallate, 1,2,4-benzenetriol, and tiron.

### —Hydroxylamine Compound—

The hydroxylamine compound refers to at least one selected from the group consisting of a hydroxylamine (NH₂OH), a hydroxylamine derivative, and their salts. The hydroxylamine derivative refers to a compound of hydroxylamine (NH₂OH) obtained through substitution with at least one organic group.

A salt of the hydroxylamine or the hydroxylamine derivative may be an inorganic or organic acid salt of the hydroxylamine or the hydroxylamine derivative. For the salt of the hydroxylamine or the hydroxylamine derivative, preferred is a salt thereof with an inorganic acid in which at least one non-metal selected from the group consisting of Cl, S, N and P is bonded to hydrogen, and more preferred is a hydrochloride, a sulfate, or a nitrate.

Examples of the hydroxylamine compound include a compound represented by Formula (3) below or its salt.

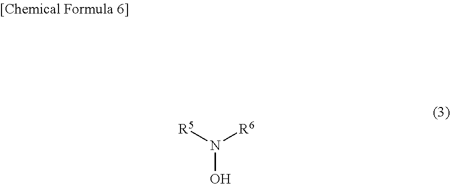

In Formula (3), R⁵ and R⁶ each independently represent a hydrogen atom or an organic group.

For the organic group represented by R⁵ and R⁶, an alkyl group having 1 to 6 carbon atoms is preferred. The alkyl group having 1 to 6 carbon atoms may be any of linear, branched and cyclic groups.

At least one of R⁵ and R⁶ is preferably an organic group (more preferably, the alkyl group having 1 to 6 carbon atoms).

For the alkyl group having 1 to 6 carbon atoms, an ethyl group or an n-propyl group is preferred, and an ethyl group is more preferred.

Examples of the hydroxylamine compound include hydroxylamine, O-methylhydroxylamine, O-ethylhydroxylamine, N-methylhydroxylamine, N,N-dimethylhydroxylamine, N,O-dimethylhydroxylamine, N-ethylhydroxylamine, N,N-diethylhydroxylamine, N,O-diethylhydroxylamine, O,N,N-trimethylhydroxylamine, N,N-dicarboxyethylhydroxylamine, and N,N-disulfoethylhydroxylamine.

Of these, N-ethylhydroxylamine, N,N-diethylhydroxylamine (DEHA), or N-n-propylhydroxylamine is preferred, and DEHA is more preferred.

### —Hydrazide Compound—

The hydrazide compound refers to a compound obtained by substituting a hydroxy group of an acid with a hydrazino group (—NH—NH₂), as well as its derivative (a compound with a hydrazino group having at least one substituent).

The hydrazide compound may have two or more hydrazino groups.

Examples of the hydrazide compound include carboxylic acid hydrazide and sulfonic acid hydrazide, with carbohydrazide (CHZ) being preferred.

### —Reducing Sulfur Compound—

The reducing sulfur compound is not particularly limited as long as it contains a sulfur atom and functions as the reducing agent, and examples thereof include mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, 3,3′-thiodi(1,2-propanediol) (dithioglycerol), sodium 3-mercapto-1-propanesulfonate, 2-mercaptoethanol, thioglycolic acid, and 3-mercapto-1-propanol.

Of these, a compound having an SH group (mercapto compound) is preferred, 1-thioglycerol, 3,3′-thiodi(1,2-propanediol), sodium 3-mercapto-1-propanesulfonate, 2-mercaptoethanol, 3-mercapto-1-propanol, or thioglycolic acid is more preferred, and 1-thioglycerol or 3,3′-thiodi(1,2-propanediol) is even more preferred.

For the reducing agent, the ascorbic acid compound, the reducing sulfur compound, or the hydroxylamine compound is preferred, and the hydroxylamine compound is more preferred.

The reducing agents may be used singly or in combination of two or more. The cleaning liquid preferably contains two or more reducing agents because this leads to more excellent corrosion prevention performance (particularly with respect to a W-containing metal film).

When the cleaning liquid contains the reducing agent, the reducing agent content is not particularly limited and is preferably 0.01 to 20 mass % and more preferably 0.1 to 5 mass % based on the total mass of the cleaning liquid.

Further, when the cleaning liquid contains the reducing agent, the reducing agent content is preferably 1 to 60 mass % and more preferably 3 to 30 mass % based on the total mass of components, excluding a solvent, in the cleaning liquid.

Those reducing agents for use may be commercial products or composites synthesized by a known method.

<Polyhydroxy Compound Having Molecular Weight of not Less than 500>

The cleaning liquid may contain a polyhydroxy compound having a molecular weight of not less than 500.

The polyhydroxy compound is an organic compound having 2 or more (e.g., 2 to 200) alcoholic hydroxy groups in the molecule. The polyhydroxy compound is a compound different from the foregoing components.

The molecular weight of the polyhydroxy compound (the weight-average molecular weight when the compound has a molecular weight distribution) is not less than 500 and preferably 500 to 3000.

Examples of the polyhydroxy compound include polyoxyalkylene glycols such as polyethylene glycol, polypropylene glycol, and polyoxyethylene polyoxypropylene glycol, oligosaccharides such as manninotriose, cellotriose, gentianose, raffinose, melezitose, cellotetrose, and stachyose, and polysaccharides such as starch, glycogen, cellulose, chitin, and chitosan, as well as their hydrolysates.

For the polyhydroxy compound, cyclodextrin is also preferred. The cyclodextrin is a cyclic oligosaccharide having a cyclic structure in which plural D-glucoses are bonded by a glucosidic bond. For the cyclodextrin, a compound in which 5 or more (e.g., 6 to 8) glucoses are bonded together is known.

Examples of the cyclodextrin include α-cyclodextrin, β-cyclodextrin, and γ-cyclodextrin, with γ-cyclodextrin being preferred.

The polyhydroxy compounds may be used singly or in combination of two or more.

When the cleaning liquid contains the polyhydroxy compound, the content thereof is preferably 0.001 to 10 mass %, more preferably 0.005 to 5 mass % and even more preferably 0.01 to 1 mass % based on the total mass of the cleaning liquid.

Further, when the cleaning liquid contains the polyhydroxy compound, the content thereof is preferably 0.1 to 30 mass % and more preferably 0.5 to 10 mass % based on the total mass of components, excluding a solvent, in the cleaning liquid.

### <Surfactant>

The cleaning liquid may contain a surfactant.

The surfactant is not particularly limited as long as it is a compound having a hydrophilic group and a hydrophobic group (lipophilic group) in the molecule, and examples thereof include an anionic surfactant, a cationic surfactant, a nonionic surfactant, and an amphoteric surfactant. The surfactant is a compound different from the foregoing components.

In many cases, the surfactant has a hydrophobic group selected from an aliphatic hydrocarbon group, an aromatic hydrocarbon group, and combinations thereof. The hydrophobic group that the surfactant has is not particularly limited; when the hydrophobic group contains an aromatic hydrocarbon group, the number of carbon atoms is preferably 6 or more and more preferably 10 or more. When the hydrophobic group contains no aromatic hydrocarbon group and is constituted only of an aliphatic hydrocarbon group, the number of carbon atoms is preferably 10 or more, more preferably 12 or more, and even more preferably 16 or more. The upper limit of the number of carbon atoms of the hydrophobic group is not particularly limited and is preferably not more than 20 and more preferably not more than 18.

### (Anionic Surfactant)

Examples of the anionic surfactant contained in the cleaning liquid include a phosphoric acid ester-based surfactant having a phosphoric acid ester group, a phosphonic acid-based surfactant having a phosphonic acid group, a sulfonic acid-based surfactant having a sulfo group, a carboxylic acid-based surfactant having a carboxy group, and a sulfuric acid ester-based surfactant having a sulfuric acid ester group, with those groups each acting as a hydrophilic group (acid group).

It is preferable for the cleaning liquid to contain the anionic surfactant because this leads to more excellent cleaning performance and corrosion prevention performance.

### —Phosphoric Acid Ester-Based Surfactant—

Examples of the phosphoric acid ester-based surfactant include phosphoric acid ester (alkyl ether phosphoric acid ester), polyoxyalkylene ether phosphoric acid ester, and salts thereof. While the phosphoric acid ester and the polyoxyalkylene ether phosphoric acid ester usually include both a monoester and a diester, a monoester or a diester may be used alone.

Examples of the salts of the phosphoric acid ester-based surfactant include a sodium salt, a potassium salt, an ammonium salt, and an organic amine salt.

A monovalent alkyl group that the phosphoric acid ester and the polyoxyalkylene ether phosphoric acid ester have is not particularly limited and is preferably an alkyl group having 2 to 24 carbon atoms, more preferably an alkyl group having 6 to 18 carbon atoms, and even more preferably an alkyl group having 12 to 18 carbon atoms.

A divalent alkylene group that the polyoxyalkylene ether phosphoric acid ester has is not particularly limited and is preferably an alkylene group having 2 to 6 carbon atoms and more preferably an ethylene group or a 1,2-propanediyl group. The number of repeats of an oxyalkylene group in the polyoxyalkylene ether phosphoric acid ester is preferably 1 to 12 and more preferably 3 to 10.

For the phosphoric acid ester-based surfactant, preferred is octyl phosphoric acid ester, lauryl phosphoric acid ester, tridecyl phosphoric acid ester, myristyl phosphoric acid ester, cetyl phosphoric acid ester, stearyl phosphoric acid ester, polyoxyethylene octyl ether phosphoric acid ester, polyoxyethylene lauryl ether phosphoric acid ester, or polyoxyethylene tridecyl ether phosphoric acid ester.

For the phosphoric acid ester-based surfactant, the compounds described in paragraphs [0012] to [0019] of JP 2011-040502 A can also be applied, and the contents thereof are incorporated in the present specification.

### —Phosphonic Acid-based Surfactant—

Examples of the phosphonic acid-based surfactant include alkyl phosphonic acid and polyvinyl phosphonic acid as well as aminomethyl phosphonic acid and the like described in, for instance, JP 2012-057108 A.

### —Sulfonic Acid-based Surfactant—

Examples of the sulfonic acid-based surfactant include alkyl sulfonic acid, alkylbenzene sulfonic acid, alkylnaphthalene sulfonic acid, alkyl diphenyl ether disulfonic acid, alkyl methyl taurine, sulfosuccinic acid diester, polyoxyalkylene alkyl ether sulfonic acid, and salts thereof.

A monovalent alkyl group that the sulfonic acid-based surfactant has is not particularly limited and is preferably an alkyl group having 10 or more carbon atoms and more preferably an alkyl group having 12 or more carbon atoms. The upper limit thereof is not particularly limited and is preferably not more than 24.

A divalent alkylene group that the polyoxyalkylene alkyl ether sulfonic acid has is not particularly limited and is preferably an ethylene group or a 1,2-propanediyl group. The number of repeats of an oxyalkylene group in the polyoxyalkylene alkyl ether sulfonic acid is preferably 1 to 12 and more preferably 1 to 6.

Specific examples of the sulfonic acid-based surfactant include hexanesulfonic acid, octanesulfonic acid, decanesulfonic acid, dodecanesulfonic acid, toluenesulfonic acid, cumenesulfonic acid, octylbenzenesulfonic acid, dodecylbenzenesulfonic acid (DBSA), dinitrobenzenesulfonic acid (DNBSA), and lauryl dodecylphenyl ether disulfonic acid (LDPEDSA).

In particular, a sulfonic acid-based surfactant with an alkyl group having 10 or more carbon atoms is preferred, a sulfonic acid-based surfactant with an alkyl group having 12 or more carbon atoms is more preferred, and DBSA is even more preferred.

### —Carboxylic Acid-based Surfactant—

Examples of the carboxylic acid-based surfactant include alkyl carboxylic acid, alkylbenzene carboxylic acid, and polyoxyalkylene alkyl ether carboxylic acid, and salts thereof.

A monovalent alkyl group that the carboxylic acid-based surfactant has is not particularly limited and is preferably an alkyl group having 7 to 25 carbon atoms and more preferably an alkyl group having 11 to 17 carbon atoms.

A divalent alkylene group that the polyoxyalkylene alkyl ether carboxylic acid has is not particularly limited and is preferably an ethylene group or a 1,2-propanediyl group. The number of repeats of an oxyalkylene group in the polyoxyalkylene alkyl ether carboxylic acid is preferably 1 to 12 and more preferably 1 to 6.

Specific examples of the carboxylic acid-based surfactant include lauric acid, myristic acid, palmitic acid, stearic acid, polyoxyethylene lauryl ether acetic acid, and polyoxyethylene tridecyl ether acetic acid.

### —Sulfuric Acid Ester-Based Surfactant—

Examples of the sulfuric acid ester-based surfactant include sulfuric acid ester (alkyl ether sulfuric acid ester), polyoxyalkylene ether sulfuric acid ester, and salts thereof.

A monovalent alkyl group that the sulfuric acid ester and the polyoxyalkylene ether sulfuric acid ester have is not particularly limited and is preferably an alkyl group having 2 to 24 carbon atoms and more preferably an alkyl group having 6 to 18 carbon atoms.

A divalent alkylene group that the polyoxyalkylene ether sulfuric acid ester has is not particularly limited and is preferably an ethylene group or a 1,2-propanediyl group. The number of repeats of an oxyalkylene group in the polyoxyalkylene ether sulfuric acid ester is preferably 1 to 12 and more preferably 1 to 6.

Specific examples of the sulfuric acid ester-based surfactant include lauryl sulfuric acid ester, myristyl sulfuric acid ester, and polyoxyethylene lauryl ether sulfuric acid ester.

For the anionic surfactant, preferred is at least one selected from the group consisting of the phosphoric acid ester-based surfactant, the sulfonic acid-based surfactant (more preferably, a sulfonic acid-based surfactant with an alkyl group having 12 or more carbon atoms), the phosphonic acid-based surfactant, and the carboxylic acid-based surfactant, and more preferred is the phosphoric acid ester-based surfactant, or a sulfonic acid-based surfactant with an alkyl group having 12 or more carbon atoms.

The anionic surfactants may be used singly or in combination of two or more. The cleaning liquid preferably contains two or more anionic surfactants because this leads to more excellent corrosion prevention performance (particularly with respect to a Cu- and/or Co-containing metal film).

When the cleaning liquid contains the anionic surfactant, the content thereof is preferably 0.01 to 5.0 mass % and more preferably 0.05 to 2.0 mass % based on the total mass of the cleaning liquid.

Further, when the cleaning liquid contains the anionic surfactant, the content thereof is preferably 0.1 to 20 mass % and more preferably 0.5 to 10 mass % based on the total mass of components, excluding a solvent, in the cleaning liquid.

Commercial products may be used as those anionic surfactants.

### (Cationic Surfactant)

Examples of the cationic surfactant include primary to tertiary alkylamine salts (e.g., monostearyl ammonium chloride, distearyl ammonium chloride, and tristearyl ammonium chloride), and modified aliphatic polyamine (e.g., polyethylene polyamine).

### (Nonionic Surfactant)

Examples of the nonionic surfactant include polyoxyalkylene alkyl ether (e.g., polyoxyethylene stearyl ether), polyoxyalkylene alkenyl ether (e.g., polyoxyethylene oleyl ether), polyoxyethylene alkyl phenyl ether (e.g., polyoxyethylene nonyl phenyl ether), polyoxyalkylene glycol (e.g., polyoxypropylene polyoxyethylene glycol), polyoxyalkylene monoalkylate (monoalkyl fatty acid ester polyoxyalkylene) (e.g., polyoxyethylene monoalkylates such as polyoxyethylene monostearate and polyoxyethylene monooleate), polyoxyalkylene dialkylate (dialkyl fatty acid ester polyoxyalkylene) (e.g., polyoxyethylene dialkylates such as polyoxyethylene distearate and polyoxyethylene dioleate), bispolyoxyalkylene alkylamide (e.g., bispolyoxyethylene stearylamide), sorbitan fatty acid ester, polyoxyethylene sorbitan fatty acid ester, polyoxyethylene alkylamine, glycerine fatty acid ester, oxyethylene-oxypropylene block copolymer, acetylene glycol-based surfactant, and acetylene-based polyoxyethylene oxide.

### (Amphoteric Surfactant)

Examples of the amphoteric surfactant include carboxy betaine (e.g., alkyl-N,N-dimethylaminoacetic acid betaine and alkyl-N,N-dihydroxyethylaminoacetic acid betaine), sulfo betaine (e.g., alkyl-N,N-dimethylsulfoethylene ammonium betaine), and imidazolinium betaine (e.g., 2-alkyl-N-carboxymethyl-N-hydroxyethylimidazolinium betaine).

For the surfactant, the compounds described in paragraphs [0092] to [0096] of JP 2015-158662 A, paragraphs [0045] to [0049] of JP 2012-151273 A, and paragraphs [0014] to [0020] of JP 2009-147389 A can also be applied, and the contents thereof are incorporated in the present specification.

The surfactants may be used singly or in combination of two or more. When the cleaning liquid contains the surfactant, the content thereof is preferably 0.01 to 5.0 mass % and more preferably 0.05 to 2.0 mass % based on the total mass of the cleaning liquid.

Further, when the cleaning liquid contains the surfactant, the content thereof is preferably 0.1 to 20 mass % and more preferably 0.5 to 10 mass % based on the total mass of components, excluding a solvent, in the cleaning liquid.

### <Nitrogen-Containing Heteroaromatic Compound>

The nitrogen-containing heteroaromatic compound is not particularly limited as long as it is a compound having a heteroaromatic ring (nitrogen-containing heteroaromatic ring) in which at least one of atoms constituting the ring is a nitrogen atom. The nitrogen-containing heteroaromatic compound serves as an anticorrosive that improves corrosion prevention performance of the cleaning liquid. Accordingly, it is preferable for the cleaning liquid to contain the nitrogen-containing heteroaromatic compound.

The nitrogen-containing heteroaromatic compound is not particularly limited, and examples thereof include an azole compound, a pyridine compound, a pyrazine compound, and a pyrimidine compound.

The azole compound is a compound having a five-membered heterocyclic ring containing at least one nitrogen atom and having aromatic properties. The number of nitrogen atoms included in the five-membered heterocyclic ring of the azole compound is not particularly limited, and is preferably 2 to 4 and more preferably 3 or 4.

The azole compound may have a substituent on the five-membered heterocyclic ring. Examples of the substituent include a hydroxy group, a carboxy group, a mercapto group, an amino group, an alkyl group having 1 to 4 carbon atoms that may have an amino group, and a 2-imidazolyl group.

Examples of the azole compound include an imidazole compound, a pyrazole compound, a thiazole compound, a triazole compound, and a tetrazole compound.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazolecarboxylic acid, histamine, benzimidazole, 2-aminobenzimidazole, and adenine.

Examples of the pyrazole compound include pyrazole, 4-pyrazolecarboxylic acid, 1-methylpyrazole, 3-methylpyrazole, 3-amino-5-hydroxypyrazole, 3-amino-5-methylpyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, and 5-methylbenzotriazole.

Examples of the tetrazole compound include 1H-tetrazole(1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

For the azole compound, the imidazole compound, the triazole compound, or the pyrazole compound is preferred, and 2-aminobenzimidazole, adenine, pyrazole, 3-amino-5-methylpyrazole, or 1,2,4-triazole is more preferred.

The pyridine compound is a compound having a six-membered heterocyclic ring (pyridine ring) containing one nitrogen atom and having aromatic properties.

Specific examples of the pyridine compound include pyridine, 3-aminopyridine, 4-aminopyridine, 3-hydroxypyridine, 4-hydroxypyridine, 2-acetamidopyridine, 2-cyanopyridine, 2-carboxypyridine, and 4-carboxypyridine.

The pyrazine compound is a compound having a six-membered heterocyclic ring (pyrazine ring) containing two nitrogen atoms at the para positions and having aromatic properties, and the pyrimidine compound is a compound having a six-membered heterocyclic ring (pyrimidine ring) containing two nitrogen atoms at the meta positions and having aromatic properties.

Examples of the pyrazine compound include pyrazine, 2-methylpyrazine, 2,5-dimethylpyrazine, 2,3,5-trimethylpyrazine, 2,3,5,6-tetramethylpyrazine, 2-ethyl-3-methylpyrazine, and 2-amino-5-methylpyrazine.

Examples of the pyrimidine compound include pyrimidine, 2-methylpyrimidine, 2-aminopyrimidine, and 4,6-dimethylpyrimidine, with 2-aminopyrimidine being preferred.

For the nitrogen-containing heteroaromatic compound, the azole compound or the pyrazine compound is preferred, and the azole compound is more preferred.

The nitrogen-containing heteroaromatic compounds may be used singly or in combination of two or more.

When the cleaning liquid contains the nitrogen-containing heteroaromatic compound, the content of the nitrogen-containing heteroaromatic compound in the cleaning liquid is not particularly limited and is preferably 0.01 to 10 mass % and more preferably 0.05 to 5 mass % based on the total mass of the cleaning liquid.

Further, when the cleaning liquid contains the nitrogen-containing heteroaromatic compound, the content thereof is preferably 0.1 to 30 mass % and more preferably 0.5 to 10 mass % based on the total mass of components, excluding a solvent, in the cleaning liquid.

### <Specific Chelating Agent>

The cleaning liquid may contain a specific chelating agent in which a coordination group is a nitrogen-containing group. The specific chelating agent has in the molecule two or more nitrogen-containing groups as coordination groups that form coordinate bonds with a metal ion. One example of the nitrogen-containing group that is a coordination group is an amino group.

Examples of the specific chelating agent include a biguanide compound that is a biguanide group-containing compound or a salt thereof. The number of biguanide groups that the biguanide compound has is not particularly limited and may be plural.

For the biguanide compound, the compounds described in paragraphs [0034] to [0055] of JP 2017-504190 A can be applied, and the contents thereof are incorporated in the present description.

For the biguanide group-containing compound, preferred is ethylene dibiguanide, propylene dibiguanide, tetramethylene dibiguanide, pentamethylene dibiguanide, hexamethylene dibiguanide, heptamethylene dibiguanide, octamethylene dibiguanide, 1,1′-hexamethylenebis(5-(p-chlorophenyl)biguanide) (chlorhexidine), 2-(benzyloxymethyl)pentane-1,5-bis(5-hexylbiguanide), 2-phenylthiomethyl)pentane-1,5-bis(5-phenethylbiguanide), 3-(phenylthio)hexane-1,6-bis(5-hexylbiguanide), 3-(phenylthio)hexane-1,6-bis(5-cyclohexylbiguanide), 3-(benzylthio)hexane-1,6-bis(5-hexylbiguanide), or 3-(benzylthio)hexane-1,6-bis(5-cyclohexylbiguanide), and more preferred is chlorhexidine.

For the salt of the biguanide group-containing compound, a hydrochloride, an acetate, or a gluconate is preferred, and a gluconate is more preferred.

For the specific chelating agent, a chlorhexidine gluconate (CHG) is preferred.

The specific chelating agents may be used singly or in combination of two or more.

When the cleaning liquid contains the specific chelating agent, the specific chelating agent content of the cleaning liquid is not particularly limited and is preferably 0.01 to 10 mass % and more preferably 0.05 to 5 mass % based on the total mass of the cleaning liquid.

Further, when the cleaning liquid contains the specific chelating agent, the content thereof is preferably 0.1 to 30 mass % and more preferably 0.5 to 10 mass % based on the total mass of components, excluding a solvent, in the cleaning liquid.

It is preferable for the cleaning liquid to contain both the nitrogen-containing heteroaromatic compound and the specific chelating agent because this leads to excellent cleaning performance (particularly with respect to a W-containing metal film).

When the cleaning liquid contains both the nitrogen-containing heteroaromatic compound and the specific chelating agent, the mass ratio between the content of the nitrogen-containing heteroaromatic compound and the content of the specific chelating agent in the cleaning liquid is not particularly limited and is preferably 1:20 to 20:1, more preferably 1:10 to 10:1, and even more preferably 1:5 to 5:1.

### <Additives>

The cleaning liquid may optionally contain other additives than the foregoing components. Examples of such additives include a pH adjuster, an anticorrosive (excluding the foregoing components), a polymer, a fluorine compound, and an organic solvent.

### (pH Adjuster)

The cleaning liquid may contain a pH adjuster for adjusting and maintaining the pH of the cleaning liquid. Examples of the pH adjuster include a basic compound and an acidic compound other than the foregoing components.

Examples of the basic compound include a basic organic compound and a basic inorganic compound.

The basic organic compound is a basic organic compound different from the foregoing components. Examples of the basic organic compound include amine oxide, nitro, nitroso, oxime, ketoxime, aldoxime, lactam, isocyanide compounds, and urea.

Examples of the basic inorganic compound include alkali metal hydroxide, alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

Alternatively, any of the first amine, the second amine, and the nitrogen-containing heteroaromatic compound described above may also serve as the basic compound for increasing the pH of the cleaning liquid.

Those basic compounds for use may be commercial products or composites suitably synthesized by a known method.

Examples of the acidic compound include an inorganic acid. The organic acid and the anionic surfactant described above may also serve as the acidic compound for reducing the pH of the cleaning liquid.

Examples of the inorganic acid include hydrochloric acid, sulfuric acid, sulfurous acid, nitric acid, nitrous acid, phosphoric acid, boric acid, and hexafluorophosphoric acid. Salts of the inorganic acids may also be used, and examples thereof include ammonium salts of the inorganic acids, more specifically, ammonium chloride, ammonium sulfate, ammonium sulfite, ammonium nitrate, ammonium nitrite, ammonium phosphate, ammonium borate, and ammonium hexafluorophosphate.

For the inorganic acid, phosphoric acid or phosphate is preferred, and phosphoric acid is more preferred.

As the acidic compound, a salt of the acidic compound may be used as long as it forms an acid or an acid ion (anion) in an aqueous solution.

As the acidic compound, a commercial product or a composite suitably synthesized by a known method may be used.

The pH adjusters may be used singly or in combination of two or more.

When the cleaning liquid contains the pH adjuster, the content thereof is selected depending on the types and amounts of other components and the pH of a target cleaning liquid, and is preferably 0.01 to 3 mass % and more preferably 0.05 to 1 mass % based on the total mass of the cleaning liquid.

Further, when the cleaning liquid contains the pH adjuster, the content thereof is selected depending on the types and amounts of other components and the pH of a target cleaning liquid, and is preferably 0.1 to 30 mass % and more preferably 0.5 to 10 mass % based on the total mass of components, excluding a solvent, in the cleaning liquid.

The cleaning liquid may contain another anticorrosive different from the foregoing components.

Examples of such another anticorrosive include sugars such as fructose, glucose, and ribose, polyol compounds such as ethylene glycol, propylene glycol, and glycerin, polycarboxylic acid compounds such as polyacrylic acid, polymaleic acid, and copolymers thereof, polyvinylpyrrolidone, cyanuric acid, barbituric acid and its derivatives, glucuronic acid, squaric acid, α-keto acid, adenosine and its derivatives, a purine compound and its derivatives, phenanthroline, resorcinol, hydroquinone, nicotinamide and its derivatives, flavonol and its derivatives, anthocyanin and its derivatives, and combinations thereof.

The cleaning liquid may contain another chelating agent different from an organic acid having a chelating function and the specific chelating agent. Examples of such another chelating agent include inorganic acid-based chelating agents such as a condensed phosphoric acid and its salt.

Examples of the condensed phosphoric acid and its salt include a pyrophosphoric acid and its salt, a metaphosphoric acid and its salt, a tripolyphosphoric acid and its salt, and a hexametaphosphoric acid and its salt.

For the polymer, the water-soluble polymers described in paragraphs [0043] to [0047] of JP 2016-171294 A can be applied, and the contents thereof are incorporated in the present description.

For the fluorine compound, the compounds described in paragraphs [0013] to [0015] of JP 2005-150236 A can be applied, and the contents thereof are incorporated in the present description.

For the organic solvent, any of known organic solvents may be used, and hydrophilic organic solvents such as alcohols and ketones are preferred. The organic solvents may be used singly or in combination of two or more.

The amounts of another anticorrosive, another chelating agent, the polymer, the fluorine compound, and the organic solvent for use are not particularly limited and may be suitably specified in the ranges that do not impair the effects of the invention.

The contents of the respective components above in the cleaning liquid can be measured by known methods such as gas chromatography-mass spectrometry (GC-MS), liquid chromatography-mass spectrometry (LC-MS), and ion-exchange chromatography (IC).

### [Physical Properties of Cleaning Liquid]

<pH>

The pH of the cleaning liquid of the invention is 6.0 to 12.0 at 25° C.

The pH of the cleaning liquid is preferably not less than 8.0, more preferably not less than 8.5, and even more preferably not less than 9.0 at 25° C. because this leads to more excellent corrosion prevention performance (particularly with respect to a Co- or Cu-containing metal film). At the same time, the pH of the cleaning liquid is preferably not more than 11.5 at 25° C. because this leads to more excellent corrosion prevention performance (particularly with respect to a W- or Cu-containing metal film).

The pH of the cleaning liquid may be adjusted by using the foregoing pH adjusters as well as components functioning as the pH adjuster, such as the first amine, the second amine, the nitrogen-containing heteroaromatic compound, the organic acid, and the anionic surfactant as above.

The pH of the cleaning liquid can be measured with a known pH meter by the method according to JIS Z 8802-1984.

### <Metal Content>

In the cleaning liquid, the content of each of metals (elemental metals Fe, Co, Na, K, Cu, Mg, Mn, Li, Al, Cr, Ni, Zn, Sn and Ag) contained as impurities in the liquid (calculated as the ion concentration) is preferably not more than 5 ppm by mass and more preferably not more than 1 ppm by mass. Since it is expected in manufacture of leading-edge semiconductor devices that a cleaning liquid with even higher purity should be required, the metal content is still more preferably less than 1 ppm by mass, that is, a value on the order of ppb by mass or less, particularly preferably 100 ppb by mass or less, and most preferably less than 10 ppb by mass. The lower limit thereof is not particularly limited and is preferably 0.

Exemplary methods of reducing the metal content include a refining treatment, such as distillation or filtration using ion-exchange resin or a filter, that is carried out in a stage of raw materials to be used in manufacture of the cleaning liquid or a stage after manufacture of the cleaning liquid.

Another method of reducing the metal content is the one using, as a container storing a raw material or the manufactured cleaning liquid, a container from which impurities are not largely leached, which will be described later. Still another method is providing lining of fluororesin on the portions of members that are to contact the relevant liquid, such as inner walls of pipes used in manufacture of the cleaning liquid, in order to prevent metal components from being leached from the members such as the pipes.

### <Coarse Particles>

The cleaning liquid may contain coarse particles but preferably in a small amount. The coarse particles herein refer to particles with a diameter (particle size) of 0.4 μm or more when the particle shape is assumed to be a sphere.

For the coarse particle content of the cleaning liquid, the content of particles with a particle size of 0.4 μm or more is preferably not more than 1000 particles and more preferably not more than 500 particles per milliliter of the cleaning liquid. The lower limit thereof is not particularly limited and is for instance 0. The content of particles with a particle size of 0.4 μm or more measured by one of the foregoing measurement methods is even more preferably at or below the detection limit.

The coarse particles contained in the cleaning liquid are particles of dust, dirt, organic and inorganic solid matter, and the like contained as impurities in raw materials and particles of dust, dirt, organic and inorganic solid matter, and the like entering as contaminations during preparation of the cleaning liquid, which particles remain present as particles in the cleaning liquid at the end without being dissolved.

The content of the coarse particles present in the cleaning liquid can be measured in a liquid phase with a commercial measurement device for a light scattering liquid-borne particle counting method using a laser as a light source.

One exemplary method of removing the coarse particles is a refining treatment such as filtration to be described later.

The cleaning liquid may take the form of a kit including raw materials of the cleaning liquid that are separated into plural units.

One exemplary method of having the cleaning liquid in the form of a kit involves preparing a liquid composition containing the first amine and the second amine as a first liquid and preparing a liquid composition containing the other components as a second liquid.

### [Manufacture of Cleaning Liquid]

The cleaning liquid can be manufactured by a known method. The method of manufacturing the cleaning liquid is described below in detail.

### <Liquid Preparation Step>

The method of preparing the cleaning liquid is not particularly limited, and for instance, the cleaning liquid can be manufactured by mixing the foregoing components. The order and/or timing of incorporating the foregoing components are not particularly limited; for instance, the first amine and the second amine as well as optional components are sequentially added into a vessel containing purified pure water and then stirred and mixed, while the pH adjuster is added to adjust the pH of the mixture, thereby preparing the cleaning liquid. When added to the vessel, water and those components may be added at one time or may be divided into plural portions and separately added.

A stirrer and a stirring method used in preparation of the cleaning liquid are not particularly limited, and a known device may be used as the stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

Mixing of the components in the preparation step of the cleaning liquid, a refining treatment to be described later, and storage of the manufactured cleaning liquid are carried out at a temperature of preferably not higher than 40° C. and more preferably not higher than 30° C. At the same time, not lower than 5° C. is preferred, and not lower than 10° C. is more preferred. The preparation, the treatment and/or the storage of the cleaning liquid within the above temperature range makes it possible to maintain stable performance for a long period of time.

### (Refining Treatment)

One or more of raw materials used in preparation of the cleaning liquid is preferably subjected to a refining treatment in advance. The refining treatment is not particularly limited, and examples thereof include known methods such as distillation, ion exchange, and filtration.

The degree of refining is not particularly limited, and a raw material is refined to a purity of preferably not less than 99 mass % and more preferably not less than 99.9 mass %.

Examples of specific methods of the refining treatment include a method in which a raw material is passed through ion-exchange resin or a reverse osmosis membrane (RO membrane), distillation of a raw material, and filtration to be described later.

As the refining treatment, the foregoing refining methods may be used in combination of two or more. For instance, a raw material may be firstly subjected to primary refinement in which the material is passed through a RO membrane and then to secondary refinement in which the material is passed through a refinement device made of cation exchange resin, anion exchange resin, or mixed-bed ion exchange resin.

The refining treatment may be carried out plural times.

### (Filtration)

A filter used in filtration is not particularly limited as long as it is of a type that has been conventionally used for filtration. Examples of the filter include filters made of fluororesins such as polytetrafluoroethylene (PTFE) and tetrafluoroethylene-perfluoroalkylvinylether copolymer (PFA), polyamide resins such as nylon, and polyolefin resins (including high density ones and ultra high molecular weight ones) such as polyethylene and polypropylene (PP). Preferred is a filter made of, of the above materials, a material selected from the group consisting of polyethylene, polypropylene (including high density polypropylene), fluororesin (including PTFE and PFA), and polyamide resin (including nylon), and more preferred is a filter made of fluororesin. By filtering a raw material with the filter made of such a material, foreign matter with high polarity that easily causes defects can be effectively removed.

The filter has a critical surface tension of preferably 70 to 95 mN/m and more preferably 75 to 85 mN/m. It should be noted that the value of the critical surface tension of the filter is a nominal value provided by its manufacturer. The use of the filter having a critical surface tension within the above range makes it possible to effectively remove foreign matter with high polarity that easily causes defects.

The filter has a pore size of preferably 2 to 20 nm and more preferably 2 to 15 nm. The pore size within the above range makes it possible to reliably remove fine foreign matter such as impurities and agglomerates contained in a raw material, while preventing clogging in filtration. The pore size herein can be determined by reference to a nominal value of the relevant filter manufacturer.

Filtration may be carried out only one time or two or more times. When filtration is carried out two or more times, the filters used may be the same or different.

Filtration is carried out preferably at room temperature (25° C.) or lower, more preferably at 23° C. or lower, and even more preferably at 20° C. or lower, and at the same time, preferably at 0° C. or higher, more preferably at 5° C. or higher, and even more preferably at 10° C. or higher. Filtration at a temperature within the foregoing range makes it possible to reduce the amounts of particulate foreign matter and impurities dissolved in a raw material and effectively remove foreign matter and impurities.

### (Container)

The cleaning liquid (including an embodiment of a kit or a diluted solution to be described later) can be put into a given container and stored, transported and used as long as problems such as corrosion do not occur.

For the container, preferred is a container which has high cleanliness in its interior and in which leaching of impurities from the inner wall of a storage portion of the container to the liquid is suppressed, for semiconductor applications. Examples of such a container include various containers commercially available as containers for semiconductor cleaning liquids, as exemplified by, but not limited to, the “Clean Bottle” series manufactured by Aicello Corporation and “Pure Bottle” manufactured by Kodama Plastics Co., Ltd.

For the container storing the cleaning liquid, preferred is a container whose portion to contact the liquid, such as the inner wall of its storage portion, is formed from fluororesin (perfluororesin) or metal having undergone a rust proof and metal leaching prevention treatment.

The inner wall of the container is preferably formed from one or more resins selected from the group consisting of polyethylene resin, polypropylene resin, and polyethylene-polypropylene resin, or another resin different therefrom, or a metal having undergone a rust proof and metal leaching prevention treatment such as stainless steel, Hastelloy, Inconel, or Monel.

For another resin above, fluororesin (perfluororesin) is preferred. When such a container with its inner wall being formed from fluororesin is used, defects such as leaching of oligomers of ethylene or propylene can be suppressed as compared to a container with its inner wall being formed from polyethylene resin, polypropylene resin, or polyethylene-polypropylene resin.

Specific examples of such a container with its inner wall being formed from fluororesin include FluoroPure PFA composite drums manufactured by Entegris, Inc. In addition, the containers described in page 4 of JP 3-502677 A, page 3 of the description of WO 2004/016526, and pages 9 and 16 of the description of WO 99/046309 may also be used.

In addition to the foregoing fluororesin, quartz and an electrolytically polished metal material (i.e., a metal material having undergone electrolytic polishing) may also be preferably used for the inner wall of the container.

For a metal material used in manufacture of the foregoing electrolytically polished metal material, preferred is a metal material containing at least one selected from the group consisting of chromium and nickel, with the total content of chromium and nickel being more than 25 mass % based on the total mass of the metal material. Examples of such a metal material include stainless steel and a nickel-chromium alloy.

The total content of chromium and nickel in the metal material is more preferably not less than 30 mass % based on the total mass of the metal material.

The upper limit of the total content of chromium and nickel in the metal material is not particularly limited and is preferably not more than 90 mass %.

The method of electrolytic polishing of the metal material is not particularly limited, and any known methods may be used. For instance, the methods described in paragraphs [0011] to [0014] of JP 2015-227501 A and paragraphs [0036] to [0042] of JP 2008-264929 A may be used.

Preferably, the inside of the container is washed before being filled with the cleaning liquid. For a liquid used for washing, the amount of metal impurities in the liquid is preferably reduced in advance. After being manufactured, the cleaning liquid may be bottled in such containers as gallon bottles or quart bottles, transported and stored.

In order to prevent components in the cleaning liquid from changing during storage, the inside of each container may be replaced with an inert gas (nitrogen, argon or the like) having a purity of not less than 99.99995 vol % in advance. In particular, a gas with a low moisture content is preferred. While the transportation and the storage may be carried out at normal temperature, the temperature may be controlled to fall within the range of −20° C. to 20° C. to prevent the change of properties.

### (Cleanroom)

It is preferable to conduct all of manufacture of the cleaning liquid, opening and washing of the containers, handling of the cleaning liquid such as filling, process and treatment analyses, and measurements in a cleanroom. The cleanroom preferably satisfies 14644-1 cleanroom standards. The cleanroom satisfies preferably one of ISO (International Organization for Standardization) Class 1, ISO Class 2, ISO Class 3, and ISO Class 4, more preferably ISO Class 1 or ISO Class 2, and even more preferably ISO Class 1.

### <Dilution Step>

The cleaning liquid as above is preferably subjected to a dilution step in which the cleaning liquid is diluted with a diluent such as water and then used in cleaning of semiconductor substrates.

The dilution ratio of the cleaning liquid in the dilution step may be adjusted as appropriate depending on the types and contents of components and the type of semiconductor substrates to be cleaned, and the ratio of the diluted cleaning liquid to the cleaning liquid before dilution is preferably 10 to 10000 times, more preferably 20 to 3000 times, and even more preferably 50 to 1000 times in mass ratio.

The cleaning liquid is diluted preferably with water because this leads to more excellent defect suppression performance.

The change in pH from that before dilution to that after dilution (a difference between the pH of the cleaning liquid before dilution and the pH of the diluted cleaning liquid) is preferably not more than 1.0, more preferably not more than 0.8 and even more preferably not more than 0.5.

The pH of the diluted cleaning liquid is preferably more than 7.0, more preferably not less than 7.5 and even more preferably not less than 8.0 at 25° C. The upper limit of the pH of the diluted cleaning liquid is preferably not more than 13.0, more preferably not more than 12.5 and even more preferably not more than 12.0 at 25° C.

The first amine content of the diluted cleaning liquid is preferably not less than 0.005 mass %, more preferably more than 0.01 mass %, even more preferably not less than 0.02 mass % and particularly preferably more than 0.03 mass % based on the total mass of the diluted cleaning liquid because this leads to more excellent cleaning performance (particularly with respect to a Cu- or Co-containing metal film). The upper limit thereof is not particularly limited and is preferably not more than 0.25 mass %, more preferably not more than 0.15 mass %, even more preferably not more than 0.1 mass % and particularly preferably not more than 0.07 mass % based on the total mass of the diluted cleaning liquid because this leads to more excellent corrosion prevention performance.

The second amine content of the diluted cleaning liquid is preferably not less than 0.005 mass %, more preferably not less than 0.01 mass % and even more preferably not less than 0.02 mass % based on the total mass of the diluted cleaning liquid because this leads to more excellent cleaning performance. The upper limit of the second amine content of the diluted cleaning liquid is preferably not more than 0.2 mass %, more preferably not more than 0.15 mass % and even more preferably not more than 0.1 mass % based on the total mass of the diluted cleaning liquid because this leads to excellent corrosion prevention performance with respect to a metal film.

The water content of the diluted cleaning liquid may be the balance other than the first amine, the second amine, and optional components described above. The water content is preferably not less than 99 mass %, more preferably not less than 99.3 mass %, even more preferably not less than 99.6 mass %, and particularly preferably not less than 99.85 mass % based on the total mass of the diluted cleaning liquid. The upper limit thereof is not particularly limited and is preferably not more than 99.99 mass % and more preferably not more than 99.95 mass % based on the total mass of the diluted cleaning liquid.

When the diluted cleaning liquid contains the organic acid, the content thereof is preferably 0.0001 to 0.1 mass % and more preferably 0.0005 to 0.05 mass % based on the total mass of the diluted cleaning liquid.

When the diluted cleaning liquid contains the carboxylic acid, the content thereof is preferably 0.001 to 0.1 mass % and more preferably 0.005 to 0.05 mass % based on the total mass of the diluted cleaning liquid.

When the diluted cleaning liquid contains the phosphonic acid, the content thereof is preferably 0.0001 to 0.02 mass % and more preferably 0.0005 to 0.01 mass % based on the total mass of the diluted cleaning liquid.

When the diluted cleaning liquid contains the reducing agent, the content thereof is preferably 0.0001 to 0.2 mass % and more preferably 0.001 to 0.05 mass % based on the total mass of the diluted cleaning liquid.

When the diluted cleaning liquid contains the polyhydroxy compound, the content thereof is preferably 0.00001 to 0.1 mass %, more preferably 0.00005 to 0.05 mass % and even more preferably 0.0001 to 0.01 mass % based on the total mass of the diluted cleaning liquid.

When the diluted cleaning liquid contains the surfactant (preferably the anionic surfactant), the content thereof is preferably 0.0001 to 0.05 mass % and more preferably 0.0005 to 0.02 mass % based on the total mass of the diluted cleaning liquid.

When the diluted cleaning liquid contains the nitrogen-containing heteroaromatic compound, the content thereof is preferably 0.0001 to 0.1 mass % and more preferably 0.0005 to 0.05 mass % based on the total mass of the diluted cleaning liquid.

When the diluted cleaning liquid contains the specific chelating agent, the content thereof is not particularly limited and is preferably 0.0001 to 0.1 mass % and more preferably 0.0005 to 0.05 mass % based on the total mass of the diluted cleaning liquid.

When the diluted cleaning liquid contains the pH adjuster, the content thereof is selected depending on the types and amounts of other components and the pH of a target diluted cleaning liquid, and is preferably 0.0001 to 0.03 mass % and more preferably 0.0005 to 0.01 mass % based on the total mass of the diluted cleaning liquid.

A specific method of diluting the cleaning liquid in the dilution step is not particularly limited, and the dilution step may be carried out according to the liquid preparation step of the cleaning liquid described above. A stirrer and a stirring method used in the dilution step are also not particularly limited, and stirring may be carried out with a known stirrer whose examples are listed in the liquid preparation step of the cleaning liquid described above.

Water used in the dilution step is preferably subjected to a refining treatment in advance. Preferably, the diluted cleaning liquid obtained in the dilution step is also subjected to a refining treatment.

The refining treatment is not particularly limited, and examples thereof include an ionic component reduction treatment using ion-exchange resin, a RO membrane, or the like, and removal of foreign matter through filtration, which are described above as examples of the refining treatment for the cleaning liquid; preferably, one of these treatments is carried out.

### [Application of Cleaning Liquid]

The cleaning liquid is used in a cleaning step of cleaning a semiconductor substrate having undergone a chemical mechanical polishing (CMP) process. The cleaning liquid also can be used in cleaning of a semiconductor substrate in a semiconductor substrate manufacturing process and, in addition, used as a composition for buffing treatment, which will be described later.

As described above, the diluted cleaning liquid obtained by diluting the cleaning liquid may be used in cleaning of a semiconductor substrate.

### [Cleaning Object]

One example of a cleaning object to be cleaned with the cleaning liquid is a semiconductor substrate having metal-containing matter.

The expression “on a semiconductor substrate” in this specification includes places on the top, bottom and lateral sides of the semiconductor substrate and in a groove of the semiconductor substrate. The metal-containing matter on a semiconductor substrate includes not only metal-containing matter present directly on a surface of the semiconductor substrate but also metal-containing matter present on or above the semiconductor substrate via another layer.

A metal contained in the metal-containing matter is for instance at least one metal M selected from the group consisting of Cu (copper), Co (cobalt), W (tungsten), Ti (titanium), Ta (tantalum), Ru (ruthenium), Cr (chromium), Hf (hafnium), Os (osmium), Pt (platinum), Ni (nickel), Mn (manganese), Zr (zirconium), Mo (molybdenum), La (lanthanum), and Ir (iridium).

The metal-containing matter is not limited as long as it is a substance containing a metal (metallic atom), and examples thereof include a simple substance of the metal M, an alloy containing the metal M, an oxide of the metal M, a nitride of the metal M, and an oxynitride of the metal M.

The metal-containing matter may be a mixture containing two or more of those compounds.

The oxide, the nitride and the oxynitride above may be a composite oxide, a composite nitride and a composite oxynitride each of which contains a metal.

The metallic atom content of the metal-containing matter is preferably not less than 10 mass %, more preferably not less than 30 mass % and even more preferably not less than 50 mass % based on the total mass of the metal-containing matter. The upper limit thereof is 100 mass % because the metal-containing matter may be exactly the metal itself.

The semiconductor substrate has preferably the metal-containing matter containing the metal M, more preferably the metal-containing matter containing at least one metal selected from the group consisting of Cu, Co, W, Ti, Ta, and Ru, and even more preferably the metal-containing matter containing at least one metal selected from the group consisting of Cu, Co, Ti, Ta, Ru, and W.

The semiconductor substrate that is a cleaning object to be cleaned with the cleaning liquid is not particularly limited, and examples thereof include one having a metal wiring film, a barrier metal, and an insulating film on a surface of a wafer constituting the semiconductor substrate.

Specific examples of the wafer constituting the semiconductor substrate include wafers made of silicon-based materials such as a silicon (Si) wafer, a silicon carbide (SiC) wafer, and a silicon-containing resin wafer (glass epoxy wafer), a gallium phosphide (GaP) wafer, a gallium arsenide (GaAs) wafer, and an indium phosphide (InP) wafer.

Applicable examples of the silicon wafer include an n-type silicon wafer in which a silicon wafer is doped with a pentavalent atom (e.g., phosphorus (P), arsenic (As), and antimony (Sb)), and a p-type silicon wafer in which a silicon wafer is doped with a trivalent atom (e.g., boron (B), and gallium (Ga)). A silicon of the silicon wafer may be any of, for example, amorphous silicon, monocrystalline silicon, polycrystalline silicon, and polysilicon.

In particular, the cleaning liquid is useful for wafers made of silicon-based materials such as the silicon wafer, the silicon carbide wafer, and the silicon-containing resin wafer (glass epoxy wafer).

The semiconductor substrate may have an insulating film on the wafer described above.

Specific examples of the insulating film include silicon oxide films (e.g., a silicon dioxide (SiO₂) film and a tetraethyl orthosilicate (Si(OC₂H₅)₄) film (TEOS film)), silicon nitride films (e.g., a silicon nitride (Si₃N₄) film and a silicon nitride/carbide (SiNC) film), and low dielectric (Low-k) films (e.g., a carbon-doped silicon oxide (SiOC) film and a silicon carbide (SiC) film).

Examples of a metal film that the semiconductor substrate has include a metal film containing at least one metal selected from copper (Cu), cobalt (Co), and tungsten (W), as exemplified by a film primarily composed of copper (copper-containing film), a film primarily composed of cobalt (cobalt-containing film), a film primarily composed of tungsten (tungsten-containing film), and a metal film constituted of an alloy including one or more selected from the group consisting of Cu, Co and W.

Preferably, the semiconductor substrate has a metal film containing at least one selected from the group consisting of copper and cobalt. It is also preferable for the semiconductor substrate to have a metal film containing tungsten.

Examples of the copper-containing film include a wiring film composed only of metallic copper (copper wiring film) and a wiring film made of an alloy composed of metallic copper and other metals (copper alloy wiring film).

Specific examples of the copper alloy wiring film include a wiring film made of an alloy composed of copper and one or more metals selected from aluminum (Al), titanium (Ti), chromium (Cr), manganese (Mn), tantalum (Ta) and tungsten (W). More specifically, examples thereof include a copper-aluminum alloy wiring film (CuAl alloy wiring film), a copper-titanium alloy wiring film (CuTi alloy wiring film), a copper-chromium alloy wiring film (CuCr alloy wiring film), a copper-manganese alloy wiring film (CuMn alloy wiring film), a copper-tantalum alloy wiring film (CuTa alloy wiring film), and a copper-tungsten alloy wiring film (CuW alloy wiring film).

Examples of the cobalt-containing film (a metal film primarily composed of cobalt) include a metal film composed only of metallic cobalt (cobalt metal film) and a metal film made of an alloy composed of metallic cobalt and other metals (cobalt alloy metal film).

Specific examples of the cobalt alloy metal film include a metal film made of an alloy composed of cobalt and one or more metals selected from titanium (Ti), chromium (Cr), iron (Fe), nickel (Ni), molybdenum (Mo), palladium (Pd), tantalum (Ta) and tungsten (W). More specifically, examples thereof include a cobalt-titanium alloy metal film (CoTi alloy metal film), a cobalt-chromium alloy metal film (CoCr alloy metal film), a cobalt-iron alloy metal film (CoFe alloy metal film), a cobalt-nickel alloy metal film (CoNi alloy metal film), a cobalt-molybdenum alloy metal film (CoMo alloy metal film), a cobalt-palladium alloy metal film (CoPd alloy metal film), a cobalt tantalum alloy metal film (CoTa alloy metal film), and a cobalt-tungsten alloy metal film (CoW alloy metal film).

The cleaning liquid is useful for a substrate having the cobalt-containing film. Of the cobalt-containing films, the cobalt metal film is often used as a wiring film, and the cobalt alloy metal film is often used as a barrier metal.

In some cases, it is preferable to use the cleaning liquid in cleaning of the semiconductor substrate having at least the copper-containing wiring film and the metal film (cobalt barrier metal), which is composed only of metallic cobalt and is a barrier metal of the copper-containing wiring film, on or above the wafer constituting the substrate, with the copper-containing wiring film and the cobalt barrier metal being in contact with each other at a surface of the substrate.

Examples of the tungsten-containing film (a metal film primarily composed of tungsten) include a metal film composed only of metallic tungsten (tungsten metal film) and a metal film made of an alloy composed of tungsten and other metals (tungsten alloy metal film).

Specific examples of the tungsten alloy metal film include a tungsten-titanium alloy metal film (WTi alloy metal film) and a tungsten-cobalt alloy metal film (WCo alloy metal film).

The tungsten-containing film is often used as a barrier metal.

The methods of forming the foregoing insulating film, copper-containing wiring film, cobalt-containing film and tungsten-containing film on the wafer constituting the semiconductor substrate are not particularly limited as long as they are known methods used in this field.

One exemplary method of forming the insulating film is a method in which the wafer constituting the semiconductor substrate is subjected to a heating treatment in the presence of oxygen gas to form a silicon oxide film, whereafter silane and ammonia gases are introduced to form a silicon nitride film by a chemical vapor deposition (CVD) method.

Exemplary methods of forming the copper-containing wiring film, the cobalt-containing film and the tungsten-containing film include a method in which a circuit is formed on the above wafer having the insulating film by a known method using a resist for instance, whereafter the copper-containing wiring film, the cobalt-containing film and the tungsten-containing film are formed by plating, the CVD method, and other methods.

### <CMP Process>

The CMP process is, for instance, a process for planarizing a surface of the substrate having the metal wiring film, the barrier metal and the insulating film through a combination of a chemical action induced by use of a polishing slurry containing fine abrasive particles (abrasive grains) and mechanical polishing.

Abrasive grains (e.g., silica and alumina) used in the CMP process, metal impurities (metal residues) derived from the polished metal wiring film and barrier metal, and other impurities sometimes remain on the surface of the semiconductor substrate having undergone the CMP process. These impurities may cause, for instance, a short-circuit between wirings and adversely affect electric characteristics of the semiconductor substrate; therefore, the semiconductor substrate having undergone the CMP process is subjected to a cleaning treatment to remove these impurities from the surface of the semiconductor substrate.

Specific examples of the semiconductor substrate having undergone the CMP process include, but not limited to, a substrate having undergone the CMP process described in Journal of the Japan Society for Precision Engineering, Vol. 84, No. 3, 2018.

### <Buffing Treatment>

A surface of the semiconductor substrate that is a cleaning object to be cleaned with the cleaning liquid may be subjected to a buffing treatment after the CMP process.

The buffing treatment is a treatment for reducing impurities on a surface of the semiconductor substrate by means of a polishing pad. Specifically, a surface of the semiconductor substrate having undergone the CMP process and the polishing pad are brought into contact with each other, and the semiconductor substrate and the polishing pad are moved to slide relatively to each other while a buffing composition is supplied to the contact portion therebetween. As a consequence, impurities on the surface of the semiconductor substrate are removed due to a frictional force caused by the polishing pad and a chemical action caused by the buffing composition.

For the buffing composition, a known buffing composition may be suitably used in accordance with the type of the semiconductor substrate and the types and amounts of impurities to be removed. Components contained in the buffing composition are not particularly limited, and examples thereof include a water-soluble polymer such as a polyvinyl alcohol, water serving as a dispersion medium, and an acid such as a nitric acid.

One preferable embodiment of the buffing treatment is subjecting the semiconductor substrate to the buffing treatment using the foregoing cleaning liquid as the buffing composition.

A polishing device and polishing conditions used in the buffing treatment are suitably selected from known devices and conditions in accordance with the type of the semiconductor substrate and substances to be removed. For the buffing treatment, for example, the treatment described in paragraphs [0085] to [0088] of WO 2017/169539 can be applied, and the contents thereof are incorporated in the present specification.

### [Method of Cleaning Semiconductor Substrates]

The method of cleaning semiconductor substrates is not particularly limited as long as it includes a cleaning step of cleaning the semiconductor substrate having undergone the CMP process by use of the foregoing cleaning liquid. It is preferable that the method of cleaning semiconductor substrates include a cleaning step in which the diluted cleaning liquid obtained in the foregoing dilution step is applied to the semiconductor substrate having undergone the CMP process to thereby clean the semiconductor substrate.

The cleaning step of cleaning the semiconductor substrate with the cleaning liquid is not particularly limited as long as it is a known method used for semiconductor substrates having undergone the CMP process, and any of known methods used in this field may be suitably employed, as exemplified by brush scrubbing cleaning that, while supplying the cleaning liquid to the semiconductor substrate, brings a cleaning member such as a brush into physical contact with a surface of the semiconductor substrate to remove residues and the like, an immersion method in which the semiconductor substrate is immersed in the cleaning liquid, a spinning (dropping) method in which the cleaning liquid is dropped while the semiconductor substrate is rotated, or a spraying method in which the cleaning liquid is sprayed. In cleaning by the immersion method, the cleaning liquid having the semiconductor substrate immersed therein is preferably subjected to an ultrasonic treatment because this can further reduce impurities remaining on the surface of the semiconductor substrate.

The cleaning step may be carried out only one time or two or more times. When the cleaning step is carried out two or more times, the same method may be repeated or different methods may be combined.

For the method of cleaning semiconductor substrates, any of a single wafer process and a batch process may be employed. The single wafer process is a method in which semiconductor substrates are treated one by one, while the batch process is a method in which a plurality of semiconductor substrates are treated at one time.

The temperature of the cleaning liquid used in cleaning of the semiconductor substrate is not particularly limited as long as it is the temperature employed in this field. While cleaning is typically carried out at room temperature (25° C.), the temperature can be arbitrarily selected in view of improvement in cleaning properties and/or suppression of damage to a member. For instance, the temperature of the cleaning liquid is preferably 10° C. to 60° C. and more preferably 15° C. to 50° C.

The cleaning time in cleaning of the semiconductor substrate depends on the types and contents of components contained in the cleaning liquid and therefore cannot be unconditionally stated; practically, the cleaning time is preferably 10 seconds to 2 minutes, more preferably 20 seconds to 1 minute and 30 seconds, and even more preferably 30 seconds to 1 minute.

The amount of supply (feed rate) of the cleaning liquid in the cleaning step of the semiconductor substrate is not particularly limited and is preferably 50 to 5000 mL/min and more preferably 500 to 2000 mL/min.

In cleaning of the semiconductor substrate, a mechanical stirring method may be used to further enhance the cleaning ability of the cleaning liquid.

Examples of the mechanical stirring method include a method involving circulating the cleaning liquid on the semiconductor substrate, a method involving flowing or spraying the cleaning liquid on the semiconductor substrate, and a method involving stirring the cleaning liquid by ultrasonics or megasonics.

The cleaning of the semiconductor substrate may be followed by a step of rinsing and washing the semiconductor substrate with a solvent (hereinafter called “rinsing step”).

The rinsing step is preferably a step that consecutively follows the cleaning step of the semiconductor substrate and that is carried out with a rinsing solvent (rinsing liquid) for 5 seconds to 5 minutes. The rinsing step may be carried out using the mechanical stirring method as above.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. Alternatively, an aqueous rinsing liquid with a pH of more than 8 (e.g., a diluted aqueous ammonium hydroxide) may be used.

The forgoing method of bringing the cleaning liquid into contact with the semiconductor substrate is applicable as a method of bringing the rinsing solvent into contact with the semiconductor substrate in the same manner.

The rinsing step may be followed by a drying step for drying the semiconductor substrate.

The drying method is not particularly limited, and examples thereof include spin drying, a method involving flowing dry gas on the semiconductor substrate, a method involving heating the substrate by a heating means such as a hot plate or an infrared lamp, Marangoni drying, Rotagoni drying, isopropyl alcohol (IPA) drying, and any combinations thereof.

### Examples

The present invention is described below in further detail based on examples. The materials, amounts of use, and ratios stated in examples below may be suitably modified as long as they do not depart from the scope and spirit of the present invention. Therefore, the scope of the present invention should not be construed as being limited to the examples below.

In the examples below, the pH values of cleaning liquids were measured at 25° C. with a pH meter (type: F-74, manufactured by HORIBA, Ltd.) according to JIS Z 8802-1984.

In manufacture of cleaning liquids of Examples and Comparative Examples, handling of containers and preparation, filling, storage, analysis and measurement of the cleaning liquids were all conducted in a cleanroom with the level satisfying ISO Class 2 or lower class. In measurement of the metal content of a cleaning liquid, when the content of a substance at or below the detection limit of ordinary measurement was measured, the measurement was carried out after the cleaning liquid was concentrated to 1/100 in terms of volume, and the measurement result was converted into a value of the metal content of the liquid at the concentration before the liquid was concentrated, in order to improve the measurement accuracy.

### [Raw Materials of Cleaning Liquid]

The following compounds were used to manufacture the cleaning liquids. The components used in Examples were those classified into a semiconductor grade or a high purity grade equivalent thereto.

### [First Amine]

2-Amino-2-methyl-1-propanol (AMP): manufactured by FUJIFILM Wako Pure Chemical Corporation (corresponding to the primary amino alcohol)
2-Amino-2-methyl-1,3-dipropanol (AMPD): manufactured by FUJIFILM Wako Pure Chemical Corporation (corresponding to the primary amino alcohol)
2-Amino-2-ethyl-1,3-dipropanol (AEPD): manufactured by FUJIFILM Wako Pure Chemical Corporation (corresponding to the primary amino alcohol)
tert-Butylamine (tBA): manufactured by FUJIFILM Wako Pure Chemical Corporation
tert-Amylamine (tAA): manufactured by FUJIFILM Wako Pure Chemical Corporation

### [Second Amine]

2-(Methylamino)-2-methyl-1-propanol (N-MAMP): manufactured by FUJIFILM Wako Pure Chemical Corporation (corresponding to the amino alcohol)
Monoethanolamine (MEA): manufactured by FUJIFILM Wako Pure Chemical Corporation (corresponding to the amino alcohol)
Diethanolamine (DEA): manufactured by FUJIFILM Wako Pure Chemical Corporation (corresponding to the amino alcohol)
2-(Aminoethoxy)ethanol (AEE): manufactured by FUJIFILM Wako Pure Chemical Corporation (corresponding to the amino alcohol)
2-(Aminoethylamino)ethanol (AAE): manufactured by FUJIFILM Wako Pure Chemical Corporation (corresponding to the amino alcohol)
Tetraethylammonium hydroxide (TEAH): manufactured by FUJIFILM Wako Pure Chemical Corporation (corresponding to the quaternary ammonium compound)
Tetrabutylammonium hydroxide (TBAH): manufactured by FUJIFILM Wako Pure Chemical Corporation (corresponding to the quaternary ammonium compound)
Methyltriethylammonium hydroxide (MTEAH): manufactured by FUJIFILM Wako Pure Chemical Corporation (corresponding to the quaternary ammonium compound)
Diethyldimethylammonium hydroxide (DEDMAH): manufactured by FUJIFILM Wako Pure Chemical Corporation (corresponding to the quaternary ammonium compound)
Tetrapropylammonium hydroxide (TPAH): manufactured by FUJIFILM Wako Pure Chemical Corporation (corresponding to the quaternary ammonium compound)
2-(Dimethylamino)-2-methyl-1-propanol (DMAMP): manufactured by FUJIFILM Wako Pure Chemical Corporation (corresponding to the amino alcohol)
Tris(hydroxymethyl)aminomethane (Tris): manufactured by FUJIFILM Wako Pure Chemical Corporation

### [Organic Acid]

1-Hydroxyethylidene-1,1-diphosphonic acid (HEDPO): “Dequest 2000” manufactured by Thermphos
Gluconic acid: manufactured by FUJIFILM Wako Pure Chemical Corporation
Citric acid: manufactured by Fuso Chemical Co., Ltd.
Cysteine: manufactured by FUJIFILM Wako Pure Chemical Corporation
Adipic acid: manufactured by Tokyo Chemical Industry Co., Ltd.
β-Alanine: manufactured by FUJIFILM Wako Pure Chemical Corporation
Succinic acid: manufactured by Tokyo Chemical Industry Co., Ltd.

### [Reducing Agent, Polyhydroxy Compound]

Diethylhydroxylamine (DEHA): manufactured by FUJIFILM Wako Pure Chemical Corporation
Ascorbic acid: manufactured by FUJIFILM Wako Pure Chemical Corporation
Thioglycerol: 1-thioglycerol, manufactured by Asahi Kagaku Kogyo Co., Ltd.
Dithioglycerol: 3,3′-thiodi(1,2-propanediol)
γ-Cyclodextrin (γ-CD): manufactured by CycloChem Co., Ltd. (corresponding to the polyhydroxy compound)

### [Nitrogen-containing Heteroaromatic Compound, Specific Chelating Agent]

Adenine: manufactured by FUJIFILM Wako Pure Chemical Corporation (corresponding to the nitrogen-containing heteroaromatic compound)
Pyrazole: manufactured by FUJIFILM Wako Pure Chemical Corporation (corresponding to the nitrogen-containing heteroaromatic compound)
3-Amino-5-methylpyrazole: manufactured by Tokyo Chemical Industry Co., Ltd. (corresponding to the nitrogen-containing heteroaromatic compound)
2-Aminobenzimidazole: manufactured by FUJIFILM Wako Pure Chemical Corporation (corresponding to the nitrogen-containing heteroaromatic compound)
1,2,4-Triazole: manufactured by FUJIFILM Wako Pure Chemical Corporation (corresponding to the nitrogen-containing heteroaromatic compound)
Chlorhexidine gluconate (CHG): manufactured by FUJIFILM Wako Pure Chemical Corporation (corresponding to the specific chelating agent)

### [Anionic Surfactant]

Lauryl phosphoric acid ester: “Phosten HLP,” manufactured by Nikko Chemicals Co., Ltd.
Dodecylbenzenesulfonic acid (DBSA): manufactured by FUJIFILM Wako Pure Chemical Corporation

In addition, one of potassium hydroxide (KOH) and sulfuric acid (H₂SO₄) as the pH adjuster as well as commercial ultrapure water (manufactured by FUJIFILM Wako Pure Chemical Corporation) was used in a manufacture step of the cleaning liquids in Examples.

### [Manufacture of Cleaning Liquid]

Next, a method of manufacturing a cleaning liquid is described taking Example 1 as an example.

To ultrapure water, AMP (2-amino-2-methyl-1-propanol), N-MAMP (2-(methylamino)-2-methyl-1-propanol), HEDPO (1-hydroxyethylidene-1,1′-diphosphonic acid), DEHA (diethylhydroxylamine), and Phosten HLP were added in amounts corresponding to the contents shown in Tables 1 and 2, and subsequently the pH adjuster was added such that the pH of a prepared cleaning liquid was to be 10.5. The resulting mixture was sufficiently stirred with a stirrer, thereby obtaining a cleaning liquid of Example 1.

Cleaning liquids of Examples 2 to 57 and Comparative Examples 1 to 5 with the compositions shown in Tables 1 and 2 were manufactured according to the manufacturing method of Example 1.

In Tables, the “Amount (%)” columns provide the contents (unit: mass %) of the respective components based on the total mass of the relevant cleaning liquid. The symbol “*1” in the “pH adjuster” column represents that one of H₂SO₄ and KOH was added in such an amount that the pH of the prepared cleaning liquid was to be the value shown in the “pH” column.

The values in the “Ratio 1” column each represent a mass ratio of the first amine content (the total content when plural first amines were used; hereinafter the same applying to other components) to the second amine content (first amine content/second amine content).

The values in the “Cleaning liquid pH” column each represent the pH of the relevant cleaning liquid at 25° C. measured with the above pH meter.

### [Measurement of Metal Content]

The metal contents of the cleaning liquids manufactured in Examples and Comparative Examples were measured.

The metal contents were measured with Agilent 8800 triple quadrupole ICP-MS (for semiconductor analysis, option #200) under the following measurement conditions.

### (Measurement Conditions)

For a sample introduction system, a PFA nebulizer (for self-suction) of the type coaxial with a quartz torch, and a platinum interface cone were used. Measurement parameters for the cool plasma condition were as follows.
Radio frequency (RF) output (W): 600
Flow rate of carrier gas (L/min): 0.7
Flow rate of make-up gas (L/min): 1
Sampling depth (mm): 18

In measurement of the metal content, metal particles and metal ions were not distinguished from each other, and the total content thereof was obtained. When two or more metals were detected, the total content of the two or more metals was obtained.

The measurement results of the metal contents are shown in the “metal content (ppb)” column of Tables 1 and 2 (unit: ppb by mass). In Tables 1 and 2, the notation “<10” represents the metal content of the relevant cleaning liquid being less than 10 ppb by mass based on the total mass of the cleaning liquid.

### [Evaluation of Cleaning Performance]

Using the cleaning liquids manufactured by the foregoing method, evaluation was made on cleaning performance (residue removal performance) when a metal film having undergone chemical mechanical polishing was cleaned.

One milliliter of the cleaning liquid of each of Examples and Comparative Examples was taken and diluted 100 times in volume ratio with ultrapure water to prepare a sample of a diluted cleaning liquid.

A wafer (diameter: 8 inches) having on its surface a metal film made of copper, tungsten or cobalt was polished with FREX 300S-II (a polishing apparatus, manufactured by Ebara Corporation). For a wafer having on its surface a metal film made of copper, the wafer was polished using CSL9044C and BSL8176C (both of which are commercial names, manufactured by FUJIFILM Planar Solutions LLC.) as polishing slurries, thereby suppressing a variation in evaluation of cleaning performance that may be caused due to a polishing slurry. Similarly, for a wafer having on its surface a metal film made of cobalt, the wafer was polished using CSL5340C and CSL5250C (both of which are commercial names, manufactured by FUJIFILM Planar Solutions LLC.) as polishing slurries. For a wafer having on its surface a metal film made of tungsten, the wafer was polished using only W-2000 (commercial name, manufactured by Cabot Corporation). In each CMP process above, the polishing pressure was 2.0 psi, and the feed rate of the polishing slurry was 0.28 mL/(min·m²). The polishing time was 60 seconds.

Thereafter, the polished wafer was cleaned for 30 seconds using the sample of each diluted cleaning liquid whose temperature was adjusted to room temperature (23° C.), followed by drying.

The number of detected signals having the intensity corresponding to a defect with a length of 0.1 μm or more at the polished surface of the obtained wafer was counted using a defect detection apparatus (ComPlus II, manufactured by Applied Materials, Inc.), and the cleaning performance of the cleaning liquid was evaluated according to the following evaluation criteria. The evaluation results are shown in Tables 1 and 2. As the number of residue-induced defects detected at a polished surface of a wafer is smaller, the cleaning performance can be evaluated to be more excellent.

“A”: The number of defects per wafer being less than 200

“B”: The number of defects per wafer being not less than 200 and less than 300

“C”: The number of defects per wafer being not less than 300 and less than 500

“D”: The number of defects per wafer being not less than 500

### [Evaluation of Corrosion Prevention Performance]

The cleaning liquid of each of Examples and Comparative Examples was taken in an amount of 0.02 mL and diluted 100 times in volume ratio with ultrapure water to prepare a sample of a diluted cleaning liquid.

A wafer (diameter: 12 inches) having on its surface a metal film made of copper, tungsten or cobalt was cut to prepare a wafer coupon of 2 cm square. The thickness of each metal film was set to 200 nm. The wafer coupon was immersed in the sample of the diluted cleaning liquid (temperature: 23° C.) manufactured by the foregoing method and subjected to a 3-minute immersion treatment at a stirring rotational speed of 250 rpm. For each metal film, the copper, tungsten or cobalt content of the diluted cleaning liquid was measured before and after the immersion treatment. The corrosion rate (unit: Å/min) per unit time was calculated from the obtained measurement results. The corrosion prevention performance of each cleaning liquid was evaluated according to the following evaluation criteria. The results thereof are shown in Tables 1 to 2.

Note that a lower corrosion rate indicates better corrosion prevention performance of a cleaning liquid.

“A”: A corrosion rate of lower than 0.5 Å/min

“B”: A corrosion rate of not lower than 0.5 Å/min and lower than 1.0 Å/min

“C”: A corrosion rate of not lower than 1.0 Å/min and lower than 3.0 Å/min

“D”: A corrosion rate of not lower than 3.0 Å/min

### [Evaluation of Temporal Stability]

The cleaning liquids manufactured by the foregoing method were evaluated for the temporal stability.

A container for semiconductor cleaning liquids was filled with the cleaning liquid of each of Examples and Comparative Examples manufactured according to the foregoing method. Each container storing the cleaning liquid was placed in a constant temperature tank at room temperature (23° C.) and a humidity of 50% RH and retained in the constant temperature tank for 1 year.

One milliliter of the cleaning liquid of each of Examples and Comparative Examples having undergone the storage test was taken and diluted 100 times in volume ratio with ultrapure water to prepare a sample of a diluted cleaning liquid. Thereafter, the number of residue-induced defects at a polished surface of a wafer was counted according to the foregoing cleaning performance evaluation method.

The temporal stability of the cleaning liquid was evaluated using the counting result of the number of defects that increased from the number before the storage test to that after the storage test. The results thereof are shown in Tables 1 to 2.

“A”: An increase in the number of defects per wafer from the number before the storage test to that after the storage test being less than 50

“B”: An increase in the number of defects per wafer from the number before the storage test to that after the storage test being not less than 50 and less than 100

“C”: An increase in the number of defects per wafer from the number before the storage test to that after the storage test being not less than 100 and less than 300

“D”: An increase in the number of defects per wafer from the number before the storage test to that after the storage test being not less than 300

TABLE 1
Table 1

| | Cleaning liquid composition | | | | | | | | |
|---|---|---|---|---|---|---|---|---|---|
| | Amine compound | | | Amine compound | | | | | |
| | (First amine) | | | (Second amine) | | | | Organic acid | |
| | | | Amount | | | Amount | Ratio | | Amount |
| | Type | pKa | (%) | Type | pKa | (%) | 1 | Type | (%) |
| EX 1 | AMP | 9.72 | 5.82 | N-MAMP | 9.72 | 0.18 | 32.3 | HEDPO | 0.12 |
| EX 2 | AMP | 9.72 | 5.70 | N-MAMP | 9.72 | 0.30 | 19.0 | HEDPO | 0.12 |
| EX 3 | AMP | 9.72 | 5.58 | N-MAMP | 9.72 | 0.42 | 13.3 | HEDPO | 0.12 |
| EX 4 | AMP | 9.72 | 5.40 | N-MAMP | 9.72 | 0.60 | 9.0 | HEDPO | 0.12 |
| EX 5 | AMP | 9.72 | 5.22 | N-MAMP | 9.72 | 0.78 | 6.7 | HEDPO | 0.12 |
| EX 6 | AMP | 9.72 | 6.0 | TEAH | >14.0 | 6.0 | 1.0 | HEDPO | 0.12 |
| EX 7 | AMP | 9.72 | 6.0 | TEAH | >14.0 | 3.0 | 2.0 | HEDPO | 0.12 |
| EX 8 | AMP | 9.72 | 6.0 | TEAH | >14.0 | 1.0 | 6.0 | HEDPO | 0.12 |
| EX 9 | AMP | 9.72 | 6.0 | TEAH | >14.0 | 0.3 | 20.0 | HEDPO | 0.12 |
| EX 10 | AMP | 9.72 | 6.0 | TEAH | >14.0 | 0.06 | 100.0 | HEDPO | 0.12 |
| EX 11 | AMPD | 8.80 | 6.0 | TEAH | >14.0 | 6.0 | 1.0 | HEDPO | 0.12 |
| EX 12 | AEPD | 8.80 | 6.0 | TEAH | >14.0 | 3.0 | 2.0 | HEDPO | 0.12 |
| EX 13 | tBA | 10.68 | 6.0 | TEAH | >14.0 | 1.0 | 6.0 | HEDPO | 0.12 |
| EX 14 | tAA | 10.50 | 6.0 | TEAH | >14.0 | 0.3 | 20.0 | HEDPO | 0.12 |
| EX 15 | AMP | 9.72 | 6.0 | MEA | 9.50 | 1.0 | 6.0 | HEDPO | 0.12 |
| EX 16 | AMP | 9.72 | 6.0 | DEA | 8.70 | 1.0 | 6.0 | HEDPO | 0.12 |
| EX 17 | AMP | 9.72 | 6.0 | AEE | 10.60 | 1.0 | 6.0 | HEDPO | 0.12 |
| EX 18 | AMP | 9.72 | 6.0 | AAE | 10.80 | 1.0 | 6.0 | HEDPO | 0.12 |
| EX 19 | AMP | 9.72 | 6.0 | TBAH | >14.0 | 1.0 | 6.0 | HEDPO | 0.12 |
| EX 20 | AMP | 9.72 | 6.0 | MTEAH | >14.0 | 1.0 | 6.0 | HEDPO | 0.12 |
| EX 21 | AMP | 9.72 | 6.0 | DEDMAH | >14.0 | 1.0 | 6.0 | HEDPO | 0.12 |
| EX 22 | AMP | 9.72 | 6.0 | TPAH | >14.0 | 1.0 | 6.0 | HEDPO | 0.12 |
| EX 23 | AMP | 9.72 | 1.0 | TEAH | >14.0 | 1.0 | 1.0 | HEDPO | 0.12 |
| EX 24 | AMP | 9.72 | 3.0 | TEAH | >14.0 | 1.0 | 3.0 | HEDPO | 0.12 |
| EX 25 | AMP | 9.72 | 5.0 | TEAH | >14.0 | 1.0 | 5.0 | HEDPO | 0.12 |
| EX 26 | AMP | 9.72 | 10.0 | TEAH | >14.0 | 1.0 | 10.0 | HEDPO | 0.12 |
| EX 27 | AMP | 9.72 | 20.0 | TEAH | >14.0 | 1.0 | 20.0 | HEDPO | 0.12 |
| EX 28 | AMP | 9.72 | 6.0 | TEAH | >14.0 | 1.0 | 6.0 | HEDPO | 0.12 |
| EX 29 | AMP | 9.72 | 6.0 | TEAH | >14.0 | 1.0 | 6.0 | HEDPO | 0.12 |
| EX 30 | AMP | 9.72 | 6.0 | TEAH | >14.0 | 1.0 | 6.0 | HEDPO | 0.12 |
| EX 31 | AMP | 9.72 | 6.0 | TEAH | >14.0 | 1.0 | 6.0 | HEDPO | 0.12 |
| EX 32 | AMP | 9.72 | 6.0 | TEAH | >14.0 | 1.0 | 6.0 | HEDPO | 0.12 |
| EX 33 | AMP | 9.72 | 6.0 | TEAH | >14.0 | 1.0 | 6.0 | HEDPO | 0.12 |
| EX 34 | AMP | 9.72 | 6.0 | TEAH | >14.0 | 1.0 | 6.0 | HEDPO | 0.12 |
| | | | | | | | | Gluconic acid | 2.0 |
| EX 35 | AMP | 9.72 | 6.0 | TEAH | >14.0 | 1.0 | 6.0 | HEDPO | 0.12 |
| | | | | | | | | Citric acid | 1.0 |

Table 2

| | Cleaning liquid composition | | | | | | | |
|---|---|---|---|---|---|---|---|---|
| | Reducing | | | | Nitrogen-containing | | | |
| | agent/ | | | | heteroaromatic | | | |
| | Polyhydroxy | | | | compound/Specific | | | |
| | compound | | Anionic surfactant | | chelating agent | | | Cleaning |
| Table 1 | | Amount | | Amount | | Amount | pH | liquid |
| (Continuation) | Type | (%) | Type | (%) | Type | (%) | adjuster | pH |

| | | | | | | | | |
|---|---|---|---|---|---|---|---|---|
| EX 1 | DEHA | 1.5 | Phosten HLP | 0.5 | — | — | *1 | 10.5 |
| EX 2 | DEHA | 1.5 | Phosten HLP | 0.5 | — | — | *1 | 10.5 |
| EX 3 | DEHA | 1.5 | Phosten HLP | 0.5 | — | — | *1 | 10.5 |
| EX 4 | DEHA | 1.5 | Phosten HLP | 0.5 | — | — | *1 | 10.5 |
| EX 5 | DEHA | 1.5 | Phosten HLP | 0.5 | — | — | *1 | 10.5 |
| EX 6 | DEHA | 1.5 | Phosten HLP | 0.5 | — | — | *1 | 10.5 |
| EX 7 | DEHA | 1.5 | Phosten HLP | 0.5 | — | — | *1 | 10.5 |
| EX 8 | DEHA | 1.5 | Phosten HLP | 0.5 | — | — | *1 | 10.5 |
| EX 9 | DEHA | 1.5 | Phosten HLP | 0.5 | — | — | *1 | 10.5 |
| EX 10 | DEHA | 1.5 | Phosten HLP | 0.5 | — | — | *1 | 10.5 |
| EX 11 | DEHA | 1.5 | Phosten HLP | 0.5 | — | — | *1 | 10.5 |
| EX 12 | DEHA | 1.5 | Phosten HLP | 0.5 | — | — | *1 | 10.5 |
| EX 13 | DEHA | 1.5 | Phosten HLP | 0.5 | — | — | *1 | 10.5 |
| EX 14 | DEHA | 1.5 | Phosten HLP | 0.5 | — | — | *1 | 10.5 |
| EX 15 | DEHA | 1.5 | Phosten HLP | 0.5 | — | — | *1 | 10.5 |
| EX 16 | DEHA | 1.5 | Phosten HLP | 0.5 | — | — | *1 | 10.5 |
| EX 17 | DEHA | 1.5 | Phosten HLP | 0.5 | — | — | *1 | 10.5 |
| EX 18 | DEHA | 1.5 | Phosten HLP | 0.5 | — | — | *1 | 10.5 |
| EX 19 | DEHA | 1.5 | Phosten HLP | 0.5 | — | — | *1 | 10.5 |
| EX 20 | DEHA | 1.5 | Phosten HLP | 0.5 | — | — | *1 | 10.5 |
| EX 21 | DEHA | 1.5 | Phosten HLP | 0.5 | — | — | *1 | 10.5 |
| EX 22 | DEHA | 1.5 | Phosten HLP | 0.5 | — | — | *1 | 10.5 |
| EX 23 | DEHA | 1.5 | Phosten HLP | 0.5 | — | — | *1 | 10.5 |
| EX 24 | DEHA | 1.5 | Phosten HLP | 0.5 | — | — | *1 | 10.5 |
| EX 25 | DEHA | 1.5 | Phosten HLP | 0.5 | — | — | *1 | 10.5 |
| EX 26 | DEHA | 1.5 | Phosten HLP | 0.5 | — | — | *1 | 10.5 |
| EX 27 | DEHA | 1.5 | Phosten HLP | 0.5 | — | — | *1 | 10.5 |
| EX 28 | DEHA | 1.5 | Phosten HLP | 0.5 | Adenine | 0.30 | *1 | 10.5 |
| EX 29 | DEHA | 1.5 | Phosten HLP | 0.5 | Pyrazole | 1.00 | *1 | 10.5 |
| EX 30 | DEHA | 1.5 | Phosten HLP | 0.5 | 3-Amino-5- | 0.30 | *1 | 10.5 |
| | | | | | methylpyrazole | | | |
| EX 31 | DEHA | 1.5 | Phosten HLP | 0.5 | CHG | 0.80 | *1 | 10.5 |
| EX 32 | DEHA | 1.5 | Phosten HLP | 0.5 | 3-Amino-5- | 0.40 | *1 | 10.5 |
| | | | | | methylpyrazole | | | |
| | | | | | CHG | 0.40 | | |
| EX 33 | DEHA | 1.5 | Phosten HLP | 0.5 | 2-Amino- | 0.30 | *1 | 10.5 |
| | | | | | benzimidazole | | | |
| EX 34 | DEHA | 1.5 | Phosten HLP | 0.5 | Adenine | 0.30 | *1 | 10.5 |
| EX 35 | DEHA | 1.5 | Phosten HLP | 0.5 | Adenine | 0.30 | *1 | 10.5 |

Table 3

| | | | | | Corrosion | | | | | |
|---|---|---|---|---|---|---|---|---|---|---|
| | Metal | Cleaning | | | prevention | | | | | |
| Table 1 | content | performance | | | performance | | | Temporal stability | | |
| (Continuation) | (ppb) | Cu | W | Co | Cu | W | Co | Cu | W | Co |
| EX 1 | <10 | A | B | A | B | B | B | A | A | A |
| EX 2 | <10 | A | B | A | B | B | B | A | A | A |
| EX 3 | <10 | A | B | A | B | B | B | A | A | A |
| EX 4 | <10 | A | B | A | B | B | B | A | A | A |
| EX 5 | <10 | A | B | A | B | B | B | A | A | A |
| EX 6 | <10 | A | B | A | B | B | B | A | A | A |
| EX 7 | <10 | A | B | A | B | B | B | A | A | A |
| EX 8 | <10 | A | B | A | B | B | B | A | A | A |
| EX 9 | <10 | A | B | A | B | B | B | A | A | A |
| EX 10 | <10 | A | B | A | B | B | B | A | A | A |
| EX 11 | <10 | A | B | A | B | B | B | A | A | A |
| EX 12 | <10 | A | B | A | B | B | B | A | A | A |
| EX 13 | <10 | B | B | B | B | B | B | A | A | A |
| EX 14 | <10 | B | B | B | B | B | B | A | A | A |
| EX 15 | <10 | A | A | A | B | B | B | A | A | A |
| EX 16 | <10 | A | A | A | B | B | B | A | A | A |
| EX 17 | <10 | A | A | A | B | B | B | A | A | A |
| EX 18 | <10 | A | A | A | B | B | B | A | A | A |
| EX 19 | <10 | A | B | A | B | B | B | A | A | A |
| EX 20 | <10 | A | B | A | B | B | B | A | A | A |
| EX 21 | <10 | A | B | A | B | B | B | A | A | A |
| EX 22 | <10 | A | B | A | B | B | B | A | A | A |
| EX 23 | <10 | B | B | B | B | B | B | A | A | A |
| EX 24 | <10 | A | B | B | B | B | B | A | A | A |
| EX 25 | <10 | A | B | A | B | B | B | A | A | A |
| EX 26 | <10 | A | B | A | B | B | B | A | A | A |
| EX 27 | <10 | B | B | A | B | B | B | A | A | A |
| EX 28 | <10 | A | B | A | A | B | A | A | A | A |
| EX 29 | <10 | A | B | A | A | B | B | A | A | A |
| EX 30 | <10 | A | B | A | A | B | A | A | A | A |
| EX 31 | <10 | A | B | A | B | A | B | A | A | A |
| EX 32 | <10 | A | A | A | A | A | A | A | A | A |
| EX 33 | <10 | A | B | A | A | B | B | A | A | A |
| EX 34 | <10 | A | A | A | A | B | A | A | A | A |
| EX 35 | <10 | A | A | A | A | B | A | A | A | A |

EX: Example

TABLE 2
Table 4

| | Cleaning liquid composition | | | | | | | | |
|---|---|---|---|---|---|---|---|---|---|
| | Amine compound | | | Amine compound | | | | | |
| | (First amine) | | | (Second amine) | | | | Organic acid | |
| | | | Amount | | | Amount | Ratio | | Amount |
| | Type | pKa | (%) | Type | pKa | (%) | 1 | Type | (%) |
| EX 36 | AMP | 9.72 | 6.0 | TEAH | >14.0 | 1.0 | 6.0 | HEDPO | 0.12 |
| | | | | | | | | Cysteine | 1.0 |
| EX 37 | AMP | 9.72 | 6.0 | N-MAMP | 9.72 | 6.0 | 1.0 | HEDPO | 0.12 |
| | | | | | | | | Adipic acid | 0.30 |
| EX 38 | AMP | 9.72 | 6.0 | TEAH | >14.0 | 1.0 | 6.0 | HEDPO | 0.12 |
| EX 39 | AMP | 9.72 | 6.0 | TEAH | >14.0 | 3.0 | 3.3 | HEDPO | 0.12 |
| | AMPD | 8.80 | 4.0 | | | | | | |
| EX 40 | AMP | 9.72 | 6.0 | TEAH | >14 | 3.0 | 1.5 | HEDPO | 0.12 |
| | | | | N-MAMP | 9.70 | 1.0 | | | |
| EX 41 | AMP | 9.72 | 6.0 | TEAH | >14.0 | 3.0 | 2.0 | HEDPO | 0.12 |
| EX 42 | AMP | 9.72 | 6.0 | TEAH | >14.0 | 3.0 | 2.0 | HEDPO | 0.12 |
| | | | | | | | | Gluconic acid | 2.0 |
| | | | | | | | | Cysteine | 1.0 |
| EX 43 | AMP | 9.72 | 6.0 | TEA | 7.80 | 10.0 | 0.6 | HEDPO | 0.12 |
| EX 44 | AMP | 9.72 | 0.5 | DMAMP | 10.60 | 0.5 | 1.0 | β-Alanine | 0.3 |
| EX 45 | AMP | 9.72 | 0.5 | DMAMP | 10.60 | 0.5 | 1.0 | β-Alanine | 0.3 |
| EX 46 | AMP | 9.72 | 0.5 | DMAMP | 10.60 | 0.5 | 1.0 | β-Alanine | 0.3 |
| EX 47 | AMP | 9.72 | 0.5 | DMAMP | 10.60 | 0.5 | 1.0 | β-Alanine | 0.3 |
| EX 48 | AMP | 9.72 | 1.0 | DMAMP | 10.60 | 0.5 | 2.0 | β-Alanine | 0.3 |
| EX 49 | AMP | 9.72 | 1.5 | DMAMP | 10.60 | 0.5 | 3.0 | β-Alanine | 0.3 |
| EX 50 | AMP | 9.72 | 1.5 | DMAMP | 10.60 | 0.5 | 3.0 | β-Alanine | 0.3 |
| EX 51 | AMP | 9.72 | 3.0 | DMAMP | 10.60 | 0.5 | 6.0 | β-Alanine | 0.3 |
| EX 52 | AMP | 9.72 | 6.0 | DMAMP | 10.60 | 0.5 | 12.0 | β-Alanine | 0.3 |
| EX 53 | AMP | 9.72 | 3.0 | DMAMP | 10.60 | 3.0 | 1.0 | β-Alanine | 0.3 |
| EX 54 | AMP | 9.72 | 6.0 | DMAMP | 10.60 | 6.0 | 1.0 | β-Alanine | 0.3 |
| EX 55 | AMP | 9.72 | 1.0 | DMAMP | 10.60 | 0.5 | 2.0 | Succinic acid | 0.1 |
| EX 56 | AMP | 9.72 | 1.0 | Tris | 8.30 | 0.5 | 2.0 | β-Alanine | 0.3 |
| | | | | DMAMP | 10.60 | 0.5 | 1.0 | β-Alanine | 0.3 |
| EX 57 | AMP | 9.72 | 1.0 | Tris | 8.30 | 0.5 | | | |
| CE 1 | AMP | 9.72 | 6.0 | TEA | 7.80 | 10.0 | 0.6 | HEDPO | 0.12 |
| CE 2 | AMP | 9.72 | 6.0 | TEA | 7.80 | 0.05 | 120.0 | HEDPO | 0.12 |
| CE 3 | — | — | — | TEA | 7.80 | 0.1 | — | HEDPO | 0.12 |
| | | | | MEA | 9.50 | 6.0 | | | |
| CE 4 | AMP | 9.72 | 6.0 | — | — | — | — | HEDPO | 0.12 |
| CE 5 | — | — | — | TEAH | >14.0 | 3.0 | — | HEDPO | 0.12 |
| | | | | Tris | 8.30 | 6.0 | | | |

Table 5

| Cleaning liquid composition | |
|---|---|
| | Nitrogen-containing |

| | |
|---|---|
| Reducing agent/ | heteroaromatic compound/ |

| | | |
|---|---|---|
| Polyhydroxy compound | Anionic surfactant | Specific chelating agent |

| Table 2 | | Amount | | Amount | | Amount | pH | Cleaning |
|---|---|---|---|---|---|---|---|---|
| (Continuation) | Type | (%) | Type | (%) | Type | (%) | adjuster | liquid pH |
| EX 36 | DEHA | 1.5 | Phosten HLP | 0.5 | Adenine | 0.30 | *1 | 10.5 |
| EX 37 | DEHA | 1.5 | Phosten HLP | 0.5 | — | — | *1 | 10.5 |
| EX 38 | DEHA | 1.5 | Phosten HLP | 0.5 | Adenine | 0.30 | *1 | 10.5 |
| | Ascorbic acid | 1.0 | | | | | | |
| EX 39 | DEHA | 1.5 | Phosten HLP | 0.5 | — | — | *1 | 10.5 |
| EX 40 | DEHA | 1.5 | Phosten HLP | 0.5 | — | — | *1 | 10.5 |
| EX 41 | DEHA | 1.5 | Phosten HLP | 0.25 | — | — | *1 | 10.5 |
| | | | DBSA | 0.25 | | | | |
| EX 42 | DEHA | 1.5 | Phosten HLP | 0.5 | — | — | *1 | 10.5 |
| EX 43 | DEHA | 1.5 | Phosten HLP | 0.5 | — | — | *1 | 10.5 |
| EX 44 | γ-CD | 0.1 | — | — | — | — | *1 | 9.5 |
| | Thioglycerol- | 1.0 | | | | | | |
| EX 45 | Thioglycerol | 1.0 | — | — | — | — | *1 | 9.5 |
| EX 46 | γ-CD | 0.1 | — | — | — | — | *1 | 9.5 |
| | Dithiogtycerol | 1.0 | | | | | | |
| EX 47 | Dithioglycerol | 1.0 | — | — | — | — | *1 | 9.5 |
| EX 48 | γ-CD | 0.1 | — | — | — | — | *1 | 10.0 |
| | Thioglycerol | 1.0 | | | | | | |
| EX 49 | γ-CD | 0.1 | — | — | — | — | *1 | 10.5 |
| | Thioglycerol | 1.0 | | | | | | |
| EX 50 | γ-CD | 0.1 | — | — | 1,2,4-Triazole | 0.10 | *1 | 10.5 |
| | Thioglycerol | 1.0 | | | | | | |
| EX 51 | γ-CD | 0.1 | — | — | — | — | *1 | 11.0 |
| | Thioglycerol | 1.0 | | | | | | |
| EX 52 | γ-CD | 0.1 | — | — | — | — | *1 | 11.3 |
| | Thioglycerol | 1.0 | | | | | | |
| EX 53 | γ-CD | 0.1 | — | — | — | — | *1 | 11.5 |
| | Thioglycerol | 1.0 | | | | | | |
| EX 54 | γ-CD | 0.1 | — | — | — | — | *1 | 11.8 |
| | Thioglycerol | 1.0 | | | | | | |
| EX 55 | γ-CD | 0.1 | — | — | — | — | *1 | 10.0 |
| | Thioglycerol | 1.0 | | | | | | |
| EX 56 | γ-CD | 0.1 | — | — | — | — | *1 | 10.0 |
| | Thioglycerol | 1.0 | | | | | | |
| EX 57 | γ-CD | 0.1 | — | — | — | — | *1 | 10.0 |
| | Thioglycerol | 1.0 | | | | | | |
| CE 1 | DEHA | 1.5 | Phosten HLP | 0.5 | — | — | *1 | 10.5 |
| CE 2 | DEHA | 1.5 | Phosten HLP | 0.5 | — | — | *1 | 10.5 |
| CE 3 | DEHA | 1.5 | Phosten HLP | 0.5 | — | — | *1 | 10.5 |
| CE 4 | DEHA | 1.5 | Phosten HLP | 0.5 | — | — | *1 | 10.5 |
| CE 5 | DEHA | 1.5 | Phosten HLP | 0.5 | — | — | *1 | 10.5 |

Table 6

| | | | | | Corrosion | | | | | |
|---|---|---|---|---|---|---|---|---|---|---|
| | Metal | Cleaning | | | prevention | | | Temporal | | |
| Table 2 | content | performance | | | performance | | | stability | | |
| (Continuation) | (ppb) | Cu | W | Co | Cu | W | Co | Cu | W | Co |
| EX 36 | <10 | A | A | A | A | B | A | A | A | A |
| EX 37 | <10 | A | A | A | A | A | A | A | A | A |
| EX 38 | <10 | A | B | A | A | A | A | A | A | A |
| EX 39 | <10 | A | A | A | B | B | B | A | A | A |
| EX 40 | <10 | A | A | A | B | B | B | A | A | A |
| EX 41 | <10 | A | B | A | A | B | A | A | A | A |
| EX 42 | <10 | A | A | A | B | B | A | A | A | A |
| EX 43 | <10 | A | B | A | B | B | B | B | B | B |
| EX 44 | <10 | A | A | A | A | A | A | B | B | B |
| EX 45 | <10 | A | A | A | A | A | A | B | B | B |
| EX 46 | <10 | A | A | A | A | A | A | B | B | B |
| EX 47 | <10 | A | A | A | A | A | A | B | B | B |
| EX 48 | <10 | B | A | A | A | A | A | B | B | B |
| EX 49 | <10 | B | A | B | A | A | A | B | B | B |
| EX 50 | <10 | A | A | B | A | A | A | B | B | B |
| EX 51 | <10 | B | A | C | A | A | A | B | B | B |
| EX 52 | <10 | B | A | C | A | A | A | B | B | B |
| EX 53 | <10 | C | B | C | A | A | A | B | B | B |
| EX 54 | <10 | C | C | C | A | A | A | B | B | B |
| EX 55 | <10 | B | B | A | A | A | A | B | B | B |
| EX 56 | <10 | A | B | A | A | B | B | B | B | B |
| EX 57 | <10 | A | B | A | A | B | B | B | B | B |
| CE 1 | <10 | D | D | D | D | D | D | D | D | D |
| CE 2 | <10 | D | D | D | C | C | C | B | B | B |
| CE 3 | <10 | C | C | C | D | D | D | D | D | D |
| CE 4 | <10 | D | D | D | C | C | C | B | B | B |
| CE 5 | <10 | D | D | D | C | C | C | B | B | B |

EX: Example
CE: Comparative Example

As evident from Tables 1 to 2, it was confirmed that the cleaning liquid of the invention has excellent temporal stability and cleaning performance.

It was confirmed that when the first amine is AMP, AMPD, or AEPD, the cleaning performance with respect to a Cu- or Co-containing metal film is more excellent (comparison between Examples 8 and 11 to 14).

It was confirmed that when the first amine content is more than 1 mass % based on the total mass of the cleaning liquid, the cleaning performance with respect to a Cu-containing metal film is more excellent, and when the first amine content is more than 3 mass % based on the total mass of the cleaning liquid, the cleaning performance with respect to a Co-containing metal film is more excellent (comparison between Examples 23 to 25). It was confirmed that when the first amine content is not more than 15 mass % based on the total mass of the cleaning liquid, the cleaning performance with respect to a Cu-containing metal film is more excellent (comparison between Examples 26 and 27).

It was confirmed that when the second amine is MEA, DEA, AEE, or AAE, the cleaning performance with respect to a W-containing metal film is more excellent (comparison between Examples 5, 8 and 15 to 22).

It was confirmed that when the cleaning liquid contains two or more organic acids, the cleaning performance with respect to a W-containing metal film is more excellent (comparison between Examples 28 and 34 to 37).

It was confirmed that when the cleaning liquid contains two or more reducing agents, the corrosion prevention performance with respect to a W-containing metal film is more excellent (comparison between Examples 28 and 38).

It was confirmed that when the cleaning liquid contains the nitrogen-containing heteroaromatic compound, the corrosion prevention performance with respect to a Cu- or Co-containing metal film is more excellent (comparison between Examples 8, 28 to 30 and 33).

It was confirmed that when the cleaning liquid contains the specific chelating agent, the corrosion prevention performance with respect to a W-containing metal film is more excellent (comparison between Examples 8 and 31).

It was confirmed that when the cleaning liquid contains both the nitrogen-containing heteroaromatic compound and the specific chelating agent, the cleaning performance with respect to a W-containing metal film is more excellent (comparison between Examples 30 to 32).

It was confirmed that when the cleaning liquid contains two or more anionic surfactants, the corrosion prevention performance with respect to a Cu- or Co-containing metal film is more excellent (comparison between Examples 7 and 41).

In the foregoing evaluation test for cleaning performance, a wafer having on its surface a metal film made of copper, tungsten or cobalt was subjected to a CMP process, and then the polished surface of the wafer was subjected to a buffing treatment. In the buffing treatment, a sample of each diluted cleaning liquid whose temperature was adjusted to room temperature (23° C.) was used as the buffing composition. The buffing treatment was carried out by means of the polishing apparatus used in the foregoing CMP process under the conditions of a polishing pressure of 2.0 psi, a feed rate of the buffing composition of 0.28 mL/(min cm²) and a polishing time of 60 seconds.

Thereafter, the wafer having undergone the buffing treatment was cleaned for 30 seconds using the sample of each diluted cleaning liquid whose temperature was adjusted to room temperature (23° C.), followed by drying.

Using the polished surface of the wafer thus obtained, the cleaning performance of each cleaning liquid was evaluated according to the foregoing evaluation test method, and as a result the evaluation results similar to those of the cleaning liquids of Examples described above were confirmed.

What is claimed is:

1. A cleaning liquid for semiconductor substrates having undergone a chemical mechanical polishing process, the cleaning liquid comprising:
a first amine compound which is a compound represented by Formula (1) and whose conjugated acid has a first acidity constant of not less than 8.5; and
a second amine compound which is at least one selected from the group consisting of a primary aliphatic amine having a primary amino group in a molecule (provided that the first amine compound is excluded), a secondary aliphatic amine having a secondary amino group in a molecule, a tertiary aliphatic amine having a tertiary amino group in a molecule, and a quaternary ammonium compound that is a compound having a quaternary ammonium cation or its salt,
wherein a mass ratio of a content of the first amine compound to a content of the second amine compound is 1 to 100, and
the cleaning liquid has a pH of 6.0 to 12.0 at 25° C.,
[Chemical Formula 1] 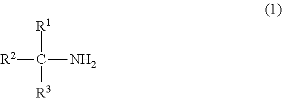
where R¹, R² and R³ each represent an organic group, and some of R¹, R² and R³ may be bonded together to form a non-aromatic ring that may have a substituent.

2. The cleaning liquid according to claim 1,
wherein a first acidity constant of a conjugated acid of the second amine compound is not less than 8.5.

3. The cleaning liquid according to claim 1,
wherein the content of the first amine compound is 0.5 to 25 mass % based on a total mass of the cleaning liquid.

4. The cleaning liquid according to claim 1,
wherein the first amine compound includes a primary amino alcohol.

5. The cleaning liquid according to claim 1,
wherein the first amine compound includes 2-amino-2-methyl-1-propanol.

6. The cleaning liquid according to claim 1,
wherein the first amine compound comprises two or more first amine compounds.

7. The cleaning liquid according to claim 1,
wherein the second amine compound includes an amino alcohol.

8. The cleaning liquid according to claim 1,
wherein the second amine compound includes 2-(methylamino)-2-methyl-1-propanol.

9. The cleaning liquid according to claim 1,
wherein the second amine compound comprises two or more second amine compounds.

10. The cleaning liquid according to claim 1, further comprising at least one selected from the group consisting of an organic acid, a reducing agent, an anionic surfactant, a nitrogen-containing heteroaromatic compound, and a specific chelating agent in which a coordination group is a nitrogen-containing group.

11. The cleaning liquid according to claim 1, further comprising two or more organic acids.

12. The cleaning liquid according to claim 1, further comprising two or more reducing agents.

13. The cleaning liquid according to claim 1, further comprising two or more anionic surfactants.

14. The cleaning liquid according to claim 1, further comprising a nitrogen-containing heteroaromatic compound.

15. The cleaning liquid according to claim 1, further comprising a specific chelating agent in which a coordination group is a nitrogen-containing group.

16. The cleaning liquid according to claim 1, further comprising both a nitrogen-containing heteroaromatic compound and a specific chelating agent in which a coordination group is a nitrogen-containing group.

17. The cleaning liquid according to claim 1,
wherein the semiconductor substrate has a metal film containing at least one selected from the group consisting of copper, tungsten, and cobalt.

18. A method of cleaning semiconductor substrates, the method comprising a step of cleaning a semiconductor substrate having undergone a chemical mechanical polishing process by applying the cleaning liquid according to claim 1 to the semiconductor substrate.
